(19) United States
(12) Patent Application Publication
(10) Pub. No.: US 2025/0321260 A1
(43) Pub. Date: Oct. 16, 2025

(54) INSPECTION DEVICE, LOADER, AND TRANSFER METHOD

(71) Applicant: Tokyo Electron Limited, Tokyo (JP)

(72) Inventors: Shuji AKIYAMA, Yamanashi (JP); Kenichi KUROSAWA, Yamanashi (JP)

(21) Appl. No.: 19/252,268

(22) Filed: Jun. 27, 2025

Related U.S. Application Data
(63) Continuation of application No. PCT/JP2023/045908, filed on Dec. 21, 2023.

(30) Foreign Application Priority Data
Jan. 11, 2023 (JP) 2023-002575

(51) Int. Cl. G01R 31/26; G01R 3/00

(52) U.S. Cl. CPC G01R 31/2601; G01R 3/00

(57) ABSTRACT

An inspection device includes a first stage that supports a substrate to be in contact with one or more contact probes, a second stage that is disposed in a vicinity of the first stage, and supports a polishing member capable of polishing the one or more contact probes, a substrate storage that stores one or more substrates including the substrate, a polishing member storage that stores one or more polishing members including the polishing member, and a transfer device including a transfer arm that transfers the substrate between the first stage and the substrate storage, and transfers the polishing member between the second stage and the polishing member storage. The transfer arm includes a first holder capable of holding the substrate, and a second holder capable of holding the polishing member at a different position from the first holder.

### CROSS-REFERENCE TO RELATED APPLICATIONS

This application is a continuation application of International Application No. PCT/JP2023/045908, filed Dec. 21, 2023, which claims propriety to Japanese Patent Application No. 2023-002575 filed Jan. 11, 2023. The contents of these applications are incorporated herein by reference.

### BACKGROUND

### 1. Field of the Invention

The present disclosure relates to inspection devices, loaders, and transfer methods.

### 2. Description of the Related Art

An inspection device (prober) is disclosed in Japanese Patent Laid-Open Publication No. 2015-138888. The disclosed inspection device is configured to perform an electrical inspection of a substrate by bringing the substrate into contact with contact probes of a probe card connected to a tester based on the three-dimensional movement of a stage on which the substrate is placed.

Moreover, the inspection device disclosed in Japanese Patent Laid-Open Publication No. 2015-138888 includes a polishing-member support unit (needle-tip polishing device) that supports a polishing member for polishing the contact probes. When the polishing member of the polishing-member support unit is replaced in the related art, the inspection operation of the inspection device is temporarily stopped, and the replacement is manually performed by a user.

### SUMMARY

According to one aspect of the present disclosure, an inspection device includes a first stage that supports a substrate to be in contact with one or more contact probes, a second stage that is disposed in a vicinity of the first stage, and supports a polishing member capable of polishing the contact probes, a substrate storage that stores one or more substrates including the substrate, a polishing member storage that stores one or more polishing members including the polishing member, and a transfer device including a transfer arm that transfers the substrate between the first stage and the substrate storage, and transfers the polishing member between the second stage and the polishing member storage. The transfer arm includes a first holder capable of holding the substrate, and a second holder capable of holding the polishing member at a different position from the first holder.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a schematic vertical cross-sectional view illustrating an inspection device according to one embodiment;

FIG. 2 is a side view illustrating a substrate support unit, a moving device, and a polishing-member support unit of the inspection device;

FIG. 3 is a plan view schematically illustrating an inspection main body and a loader;

FIG. 4 is a perspective view illustrating a transfer device;

FIG. 5 is a side view illustrating a first transfer arm and a second transfer arm;

FIG. 6 is a plan view illustrating a first end effector;

FIG. 7A is a cross-sectional view taken along the line VIIA-VIIA of FIG. 6;

FIG. 7B is a cross-sectional view taken along the line VIIB-VIIB of FIG. 6;

FIG. 8 is an explanatory diagram schematically illustrating a second suction source;

FIG. 9 is a plan view illustrating a state of a polishing member held by the first end effector;

FIG. 10 is a perspective view illustrating the loader and a polishing member storage container;

FIG. 11 is a plan view exemplifying a state of the polishing member stored in the polishing member storage container;

FIG. 12 is a perspective view illustrating a position adjustment device;

FIG. 13 is a plan view illustrating clamping performed by a clamp mechanism of the position adjustment device;

FIG. 14 is a flowchart illustrating a transfer method performed in the inspection device and an inspection method;

FIG. 15 is a flowchart illustrating a polishing member unloading action in a polishing member replacement operation;

FIG. 16A is a first diagram illustrating the polishing member unloading action;

FIG. 16B is a second diagram illustrating the polishing member unloading action;

FIG. 16C is a third diagram illustrating the polishing member unloading action;

FIG. 16D is a fourth diagram illustrating the polishing member unloading action;

FIG. 17 is a flowchart illustrating a polishing member loading action in the polishing member replacement operation;

FIG. 18A is a first diagram illustrating the polishing member loading action;

FIG. 18B is a second diagram illustrating the polishing member loading action;

FIG. 18C is a third diagram illustrating the polishing member loading action;

FIG. 18D is a fourth diagram illustrating the polishing member loading action;

FIG. 19A is a fifth diagram illustrating the polishing member loading action;

FIG. 19B is a sixth diagram illustrating the polishing member loading action;

FIG. 19C is a seventh diagram illustrating the polishing member loading action; and

FIG. 19D is a eighth diagram illustrating the polishing member loading action.

### DETAILED DESCRIPTION

Embodiments for carrying out the present disclosure will be described with reference to the drawings hereinafter. In the drawings, the same constituent component may be denoted by the same reference numeral, and redundant description may be omitted.

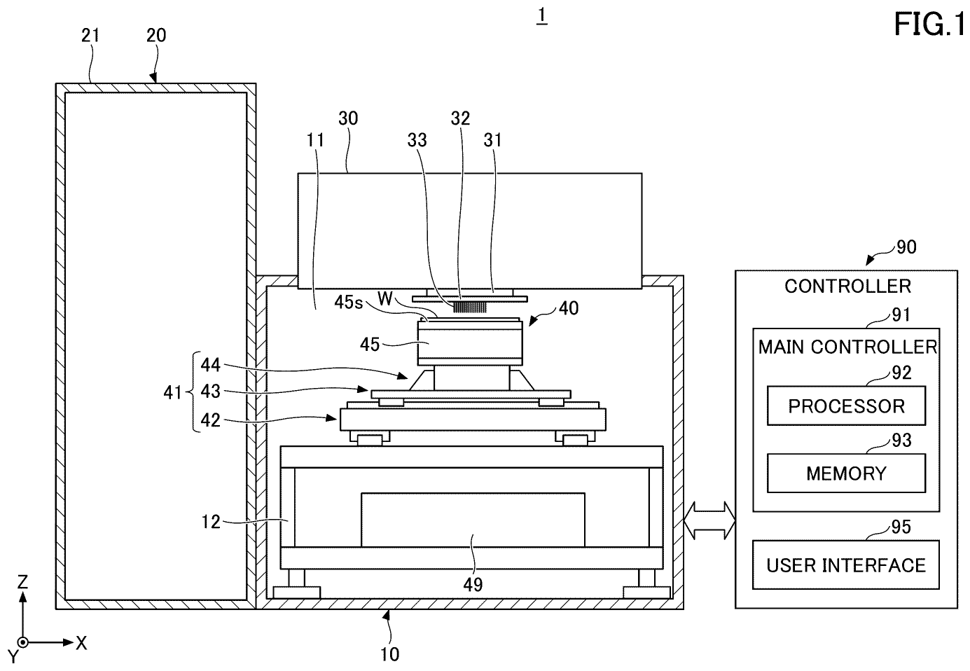

As illustrated in FIG. 1, an inspection device 1 according to one embodiment is a device that is configured to inspect electrical characteristics of inspection target devices (devices under test (DUT)) formed on a wafer W that is one example of a substrate. The support is not limited to a wafer W, and may be a carrier, a glass support, a single chip, an electronic circuit board, or the like, on each of which the inspection target devices are disposed. Examples of the inspection target devices include semiconductor devices, other electronic devices, and the like.

The inspection device 1 includes an inspection main body 10, a loader 20 disposed in the vicinity of the inspection main body 10, and a tester 30 disposed above the inspection main body 10. In addition, a controller 90 is coupled to the inspection device 1. The controller 90 controls each constituent component of the inspection device 1 to perform an inspection of a wafer W.

The inspection main body 10 includes an inspection-side housing 11 having a cuboid shape (a box shape). The inspection-side housing 11 has an inspection space inside the inspection-side housing 11. In the inspection space, a wafer W is transferred in a three-dimensional direction, and the wafer W is actually inspected. The inspection main body 10 includes a substrate support unit (a first stage) 40 on which a wafer W is placed. The substrate support unit (first stage) 40 is disposed in the inspection space. Moreover, a tester 30 is fixed onto the top of the inspection-side housing 11, and the bottom side of the tester 30 is exposed to the inspection space.

The loader 20 has wafers W on standby, loads a wafer W for an inspection into the inspection main body 10, and unloads an inspected wafer W from the inspection main body 10 under the control of a controller 90. The loader 20 includes a loader-side housing 21 accommodating constituent components of the loader 20. For example, the loader-side housing 21 is formed in a substantially cuboid shape having a height greater than the inspection-side housing 11 and the tester 30. Each of constituent components inside the loader 20 will be described in detail later.

In the tester 30, a motherboard (not illustrated) is disposed. The motherboard reproduces the circuit configuration of the wafer W having inspection target devices. The motherboard determines the performance of each of the inspection target devices based on a signal received from each of the inspection target devices of the wafer W. The tester 30 can reproduce circuit configurations of multiple types of wafers W, for example, by switching the motherboard. The tester 30 is communicably connected to the controller 90, and performs an inspection of the wafer W under the control of the controller 90.

In the tester 30, a probe card 32, which is coupled to the motherboard, is detachably held with an interface 31 at the bottom of the tester 30. The probe card 32 includes a large number of needle-like contact probes 33 disposed to correspond to a pad or a solder bump of each of the inspection targets device of the wafer W. Each of the contact probes 33 supplies electric power from the motherboard to each of the inspection target devices via the probe card 32 in the state in which each of the contact probes 33 is in contact with the wafer W, and a signal of each of the inspection target devices is transmitted to the motherboard via the probe card 32.

The inspection device 1 moves the wafer W placed on the substrate support unit 40 relative to the probe card 32 coupled to the tester 30, and allows the tester 30 to perform a test in the state in which the contact probes 33 are pressed against corresponding inspection target devices of the wafer W, respectively. The above test process is sequentially repeated while moving the substrate support unit 40 in the X-axis direction, Y-axis direction, and Z-axis direction to shift the position on the wafer so that the inspection device 1 performs inspections on all of the inspection target devices on the wafer W.

The substrate support unit 40 moves the wafer W in the three-dimensional direction (an X-axis direction, a Y-axis direction, and a Z-axis direction) in the inspection space. For example, the substrate support unit 40 is configured to transfer a wafer W from the receiving position at the loader 20 to the position facing the probe card 32 in a horizontal direction (the X-Y-axis direction). Thereafter, the substrate support unit 40 brings the wafer W into contact with corresponding probes 33 by elevating the wafer W in the upward direction (the Z-axis positive direction). Moreover, after the inspection of the wafer W, the substrate support unit 40 lowers the inspected wafer W in the downward direction (the Z-axis negative direction) to separate the wafer W from the contact probes 33, and then transfers the wafer W from the position facing the probe card 32 to the receiving position in the horizontal direction.

Specifically, the substrate support unit 40 includes a moving device 41 (a Y-axis moving mechanism 42, an X-axis moving mechanism 43, and a Z-axis moving mechanism 44) that is movable in the X-axis direction, the Y-axis direction, and the Z-axis direction, a stage 45, and a stage controller 49. Moreover, the inspection main body 10 includes a frame structure 12 that supports the moving device 41 and stage 45 of the substrate support unit 40, and the stage controller 49 in two stages, that is, upper and lower stages.

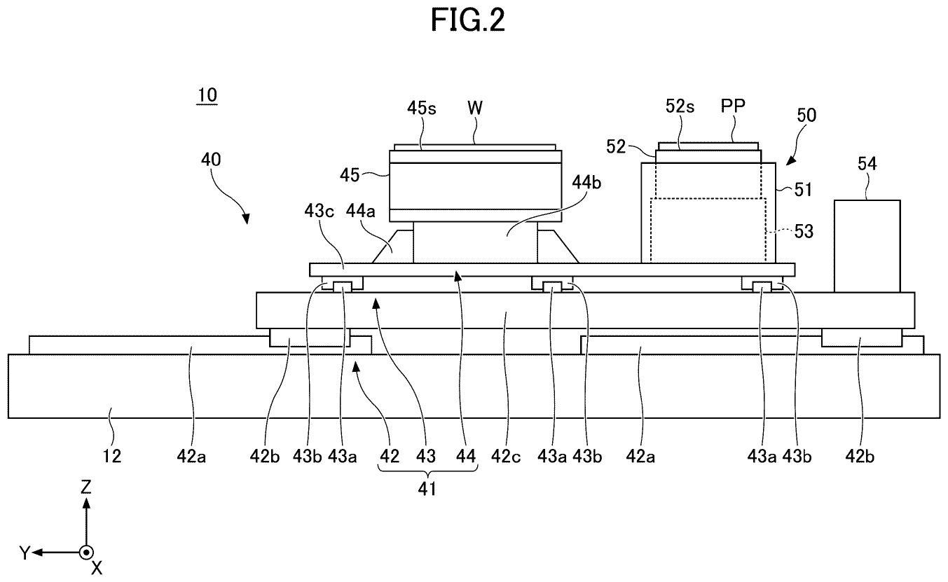

The Y-axis moving mechanism 42 is configured to move the stage 45 in the Y-axis direction. As illustrated in FIG. 2, the Y-axis moving mechanism 42 includes guide rails 42a extending along the Y-axis direction on the upper surface of the frame structure 12, Y-axis movable objects 42b provided to each guide rail 42a, and a Y-axis plate 42c that supports the Y-axis movable object 42b. Each of the Y-axis movable objects 42b is connected to a Y-axis drive (not illustrated) composed of a motor, a gear system, or the like. The Y-axis drive causes each of the movable objects 42b and the Y-axis plate 42c to advance or retreat in the Y-axis direction based on the power applied from the motor driver (not illustrated) of the stage controller 49.

Similarly, the X-axis moving mechanism 43 is configured to move the stage 45 in the X-axis direction. The X-axis moving mechanism 43 includes guide rails 43a extending along the X-axis direction on the upper surface of the Y-axis plate 42c, X-axis movable objects 43b provided to each guide rail 43a, an X-axis plate 43c supported by each of the X-axis movable objects 43b. Each of the X-axis movable objects 43b is coupled to an X-axis drive (not illustrated) composed of a motor, a gear mechanism, or the like. The X-axis drive causes each of the X-axis movable objects 43b and the X-axis plate 43c to advance or retreat in the X-axis direction based on the electric power supplied from the motor driver (not illustrated) of the stage controller 49.

The Z-axis moving mechanism 44 includes a fixing member 44a disposed on the X-axis plate 43c, and a Z-axis movable object 44b that is lifted or lowered along the Z-axis direction (the vertical direction) relative to the fixing member 44a, and holds the stage 45 on the Z-axis movable object 44b. The Z-axis movable object 44b is coupled to a Z-axis drive (not illustrated) composed of a motor, a gear mechanism, or the like. The Z-axis drive causes the Z-axis movable object 44b to move in the Z-axis direction based on electric power supplied from the motor driver (not illustrated) of the stage controller 49, thereby lifting or lowering the wafer W supported on the stage 45. The moving device 41 may have a configuration in which the stage 45 is rotated about the vertical axis (in the θ direction) as well as moving the stage 45 in the X-axis direction, the Y-axis direction, and the Z-axis direction.

The stage 45 is a member on which a wafer W is directly placed, and is transferred by the moving device 41. The upper surface of the stage 45 is a flat mounting surface 45s on which a wafer W can be placed. The stage 45 has a mechanism suitable for a holding device that holds a wafer W on the mounting surface 45s. In the case where a wafer W is held by vacuum suction, for example, the holding device may include a suction channel (not illustrated) for suction that is disposed inside the stage 45, and a pipe, a vacuum pump, or the like, which is connected to the suction channel and are disposed the outside of the stage 45. Moreover, the inspection device 1 may include a temperature-control module (not illustrated) that adjusts the temperature of the wafer W mounted on the mounting surface 45s. The temperature-control module may be disposed inside the stage 45.

Referring back to FIG. 1, the stage controller 49 is coupled to the controller 90, and controls the operation of the substrate support unit 40 according to a command from the controller 90. For example, the stage controller 49 includes an integrated controller that controls the operation of the entire substrate support unit 40, a PLC or motor driver that controls the operation of the moving device 41, an illumination controller, a power supply, and the like (none of which are illustrated).

The controller 90 of the inspection device 1 includes a main controller 91 that controls the entire inspection device 1, and a user interface 95 coupled to the main controller 91. The main controller 91 is configured by a computer, a control circuit board, or the like.

For example, the main controller 91 includes a processor 92, a memory 93, an input/output interface, which is not illustrated, and an electronic circuit. The processor 92 includes at least one selected from the group consisting of a central processing unit (CPU), a graphic processing unit (GPU), an application specific integrated circuit (ASIC), a field-programmable gate array (FPGA), and a circuit including discrete semiconductors. The memory 93 includes a volatile memory, a non-volatile memory (e.g., a compact disc, a digital versatile disc (DVD), a hard disk, a flash memory, etc.), or the like, and stores a program for operating the inspection device 1 or a recipe in which inspection contents are described.

For the user interface 95, a keyboard with which a user can input a command or the like, and a display on which the operation status of the inspection device 1 is visualized and displayed can be applied. Alternatively, devices, such as a touch panel, a mouse, a microphone, a speaker, and the like, may be applied as the user interface 95.

As illustrated in FIG. 2, moreover, the inspection device 1 according to the present embodiment includes a polishing-member support unit (second stage) 50 for polishing the contact probes 33 (see FIG. 1) of the probe card 32, which have been worn by the inspection of the wafer W. The polishing-member support unit (second stage) 50 is disposed in the inspection main body 10. The polishing-member support unit 50 is disposed, for example, on the X-axis plate 43c so that the polishing-member support unit 50 is moved together with the stage 45 in the horizontal direction by the Y-axis moving mechanism 42 and the X-axis moving mechanism 43 of the moving device 41. The polishing-member support unit 50 may be installed to be interlocked with the Z-axis movable object 44b or the stage 45.

The polishing-member support unit 50 is formed into a substantially cuboid shape, and supports a polishing member PP that is brought directly into contact with the contact probes 33 to perform polishing. The polishing-member support unit 50 includes, for example, a cylindrical outer frame 51 formed of multiple plates, a support 52 that is disposed inside the outer frame 51 and can be lifted and lowered in a vertical direction, and a lifting mechanism 53 that lifts and lowers the support 52. The lifting mechanism 53 is configured by a drive source (e.g., a motor, a cylinder, or the like) and a gear mechanism, and lifts up or lowers down the support 52 along guide columns (not illustrated) provided inside the outer frame 51.

The support 52 has a support surface 52s that has a substantially rectangular shape in a plan view. The support surface 52s is provided with a suction groove (not illustrated) for adhering the polishing member PP by suction and positioning pins (not illustrated) for positioning the polishing member PP. A suction channel (not illustrated) communicating with the suction groove of the support surface 52s is formed inside the support 52. The suction channel is coupled to a unit-side suction device 54 via a suction path provided outside the support 52. The unit-side suction device 54 includes a suction pump, a flow rate regulator, an opening/closing valve, and the like, which are not illustrated, and can apply appropriate suction pressure (negative pressure) to the suction groove.

The polishing-member support unit 50 performs, after placing a polishing member PP on the support surface 52s of the support 52, suction by the unit-side suction device 54, thereby strongly securing the polishing member PP. The inspection device 1 allows the Y-axis moving mechanism 42 and the X-axis moving mechanism 43 to perform an operation of moving the polishing member PP to a position facing the contact probes 33 of the probe card 32 in the state in which the polishing member PP is secured. Then, the inspection device 1 allows the lifting mechanism 53 to lift the support 52 to bring the polishing member PP into contact with the contact probes 33, thereby polishing the contact probes 33.

The polishing member PP set on the support surface 52s of the polishing-member support unit 50 is also gradually worn by polishing of the contact probes 33. When a worn polishing member PP is replaced in an inspection device of the related art, a user manually takes out the used polishing member PP, and sets a replacing polishing member PP to perform a replacement operation. At the time of the replacement operation, the inspection of the wafer W by the inspection device 1 is stopped.

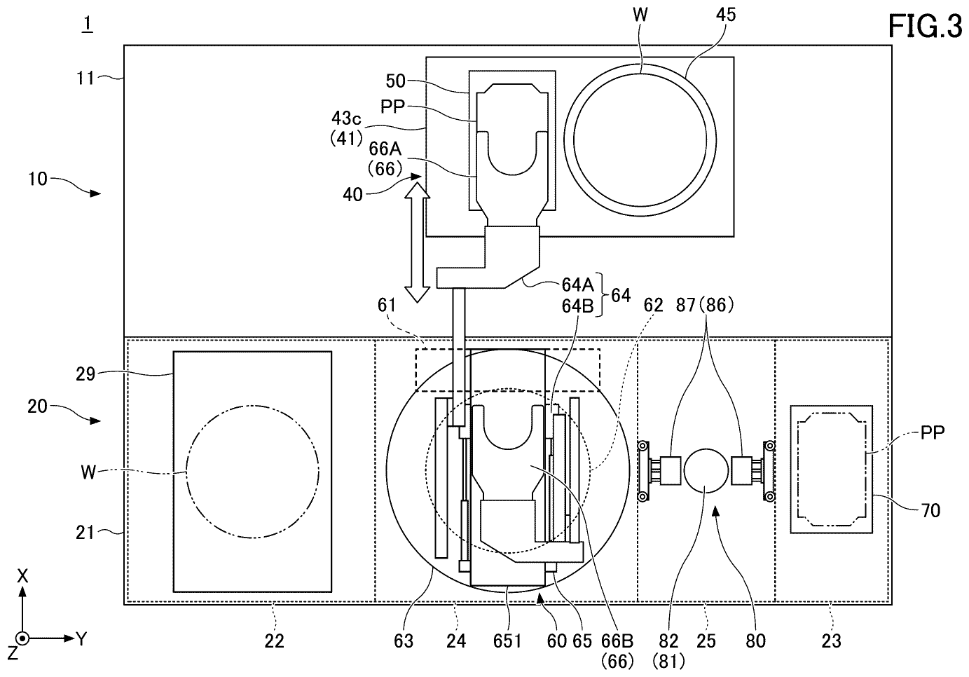

The inspection device 1 according to the present embodiment has a configuration such that a polishing member PP is automatically loaded to and unloaded from the polishing-member support unit 50 in the inspection main body 10. The configuration for transferring a polishing member PP will be specifically described with reference to FIG. 3, hereinafter.

The loader 20 includes a substrate standby region 22 in which wafers W are put on standby, and a polishing member standby region 23, in which polishing members PP are put on standby in a loader-side housing 21 having a cuboid shape that is long in the Y-axis direction in a plan view. In addition, the loader 20 includes a transfer region 24, in which a transfer device 60 is provided, between the substrate standby region 22 and the polishing member standby region 23. Specifically, in the loader 20, the substrate standby region 22, the transfer region 24, and the polishing member standby region 23 are disposed in this order in the Y-axis positive direction (direction parallel to the longitudinal direction of the inspection main body 10). Further, the loader 20 includes a position adjustment region 25, which is for adjusting the position of the polishing member PP, between the polishing member standby region 23 and the transfer region 24.

In the substrate standby region 22, a front-opening unified pod (FOUP: substrate storage) 29, which is a storage container for wafers W, is set. In the set state, a side surface of the FOUP 29 on the Y-axis positive direction side facing the transfer device 60 is open to the space of the loader-side housing 21. Thus, the transfer device 60 can smoothly access each of the wafers W aligned in the vertical direction in the substrate standby region 22. In the polishing member standby region 23, a polishing member storage container (polishing member storage) 70, in which polishing members PP can be stored, is set. A configuration of the polishing member storage container 70 will be described in detail later.

The transfer device 60 in the transfer region 24 transfers a wafer W or a polishing member PP at an appropriate timing. Specifically, the transfer device 60 performs a substrate loading action and a substrate unloading action. During the course of the substrate loading action, a wafer W to be inspected is taken out from FOUP 29, and the wafer W is passed to the substrate support unit 40. During the course of the substrate unloading action, the inspected wafer W is received from the substrate support unit 40, and the received wafer W is stored in FOUP 29. In addition, the transfer device 60 performs a polishing member loading action and a polishing member unloading action. During the course of the polishing member loading action, a replacing polishing member PP (a polishing member PP used for replacement) is taken out from the polishing member storage container 70, and the replacing polishing member PP is passed to the polishing-member support unit 50. During the course of the polishing member unloading action, the used polishing member PP is received from the polishing-member support unit 50, and the received polishing member PP is stored in the polishing member storage container 70.

The transfer device 60 is configured such that the transfer device 60 is rotatable around a vertical axis, is elevatable in the vertical direction in the transfer region 24, and is linearly movable to reciprocate from the transfer region 24 to other regions including the inspection main body 10. Therefore, the transfer device 60 includes a lifting drive 61 fixed on the loader-side housing 21, a rotation drive 62 fixed on the lifting drive 61, and a base 63 fixed on the rotation drive 62.

Moreover, the transfer device 60 according to the present embodiment includes two transfer arms 64 that directly hold a wafer W, and advance toward or retreat from the transfer region 24. Hereinafter, one of the transfer arms 64 may be referred to as a first transfer arm 64A, and the other transfer arm 64 may be referred to as a second transfer arm 64B. For example, the transfer device 60 transfers a wafer W to be inspected, which is received from FOUP 29, onto the substrate support unit 40 using the first transfer arm 64A, and takes an inspected wafer W out from the substrate support unit 40 to pass the wafer W to FOUP 29 using the second transfer arm 64B. The transfer device 60 may be configured by only one transfer arm 64 (first transfer arm 64A).

The lifting drive 61 lifts or lowers the entire transfer device 60 in the vertical direction. The lifting drive 61 includes a fixing guide, which is fixed to the loader-side housing 21 and extends in the vertical direction, a movable object movably attached to the fixing guide, and a transfer-device lifting mechanism that elevates a movable object (all not illustrated). To the movable object, a rotation drive 62 is provided. The transfer-device lifting mechanism lifts and lowers the movable object at the height in the vertical direction corresponding to the command from the controller 90.

The rotation drive 62 rotates the base 63 about the vertical axis. The rotation drive 62 includes a base portion fixed to the movable object of the lifting drive 61, a rotation shaft that is rotatable with respect to the base portion and has an upper end to which the base 63 is fixed, and a transfer-device rotation mechanism that rotates the rotation shaft (all not illustrated). The transfer-device rotation mechanism rotates the base 63 by a rotation angle corresponding to the command from the controller 90.

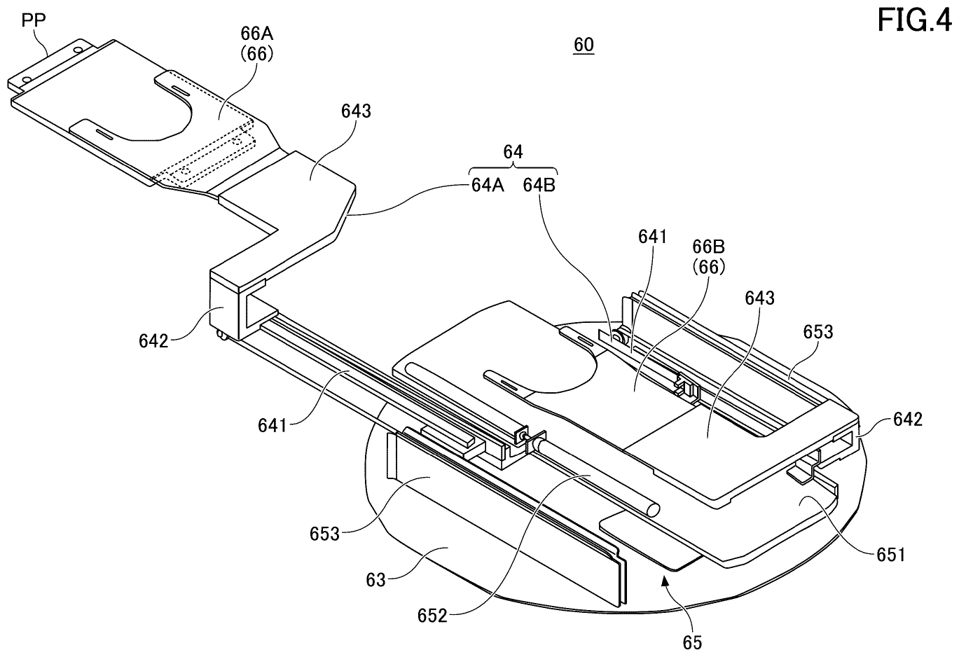

As illustrated in FIG. 4, the base 63 is formed into a disc shape, and a reciprocation drive 65 that causes the first transfer arm 64A and the second transfer arm 64B to advance or retreat is provided on an upper surface of the base 63. The reciprocation drive 65 includes a rectangular projection 651 disposed at a center of the base 63, a drive sources 652, such as cylinder mechanisms or the like, provided on both sides of the rectangular projection 651, respectively, and guide walls 653 provided parallel to the extension direction of the cylinder mechanism. Each transfer arm 64 (the first transfer arm 64A or the second transfer arm 64B) extends parallel to a corresponding guide wall 653. Thus, each transfer arm 64 linearly reciprocates along the guide wall 653 based on the driving of the drive source 652 according to the command from the controller 90.

Each transfer arm 64 (the first transfer arm 64A or the second transfer arm 64B) includes a base arm 641 guided by a corresponding guide wall 653, a linking frame 642 that is fixed to the extending end (distal end) of the base arm 641 and is projected upward by a short length, and a plate-shaped crank arm 643 that is bent inward from the upper end of the linking frame 642 toward the distal end of the crank arm 643. The base arm 641, the linking frame 642, and the crank arm 643 of the first transfer arm 64A, and the base arm 641, the linking frame 642, and the crank arm 643 of the second transfer arm 64B are respectively symmetric to each other in a plan view. At the distal end of the crank arm 643 of the first transfer arm 64A, a first end effector 66A, which is an end effector 66 of the transfer device 60, is fixed. At the distal end of the crank arm 643 of the second transfer arm 64B, a second end effector 66B, which is an end effector 66 of the transfer device 60, is fixed.

As illustrated in FIG. 5, the first transfer arm 64A and the second transfer arm 64B have mutually different heights of the projections of the linking frames 642 with respect to the base arm 641. The crank arm 643 and the end effector 66 of the first transfer arm 64A and those of the second transfer arm 64B are provided so as not to interfere with each other. In FIG. 5, the first end effector 66A is arranged above the second end effector 66B, but this arrangement may be reversed.

The first end effector 66A and the second end effector 66B can overlap each other in the vertical direction at a standby position where the first end effector 66A and the second end effector 66B are withdrawn to the base 63 side. In the case where the end effector 66 (first end effector 66A or the second end effector 66B) is located at the standby position, the transfer device 60 allows the entire transfer arm 64 (the first transfer arm 64A or the second transfer arm 64B) to be accommodated inside the disc-shaped base 63 in a plan view.

The first end effector 66A is configured such that the first end effector 66A can hold each of a wafer W and a polishing member PP. Specifically, the first end effector 66A has a first holder 67, which holds a wafer W, on an upper surface of the first end effector 66A, and has a second holder 68, which holds a polishing member PP, on a bottom surface of the first end effector 66A (at the position different from the first holder 67). In order to hold a polishing member PP at the bottom surface of the first end effector 66A, a gap between the first end effector 66A and the second end effector 66B is set to, for example, two or more times the thickness of the polishing member PP.

The second end effector 66B has only a holder (first holder 67) that holds a wafer W on the upper surface of the second end effector 66B. The second end effector 66B may be configured to be able to hold each of a wafer W and a polishing member PP.

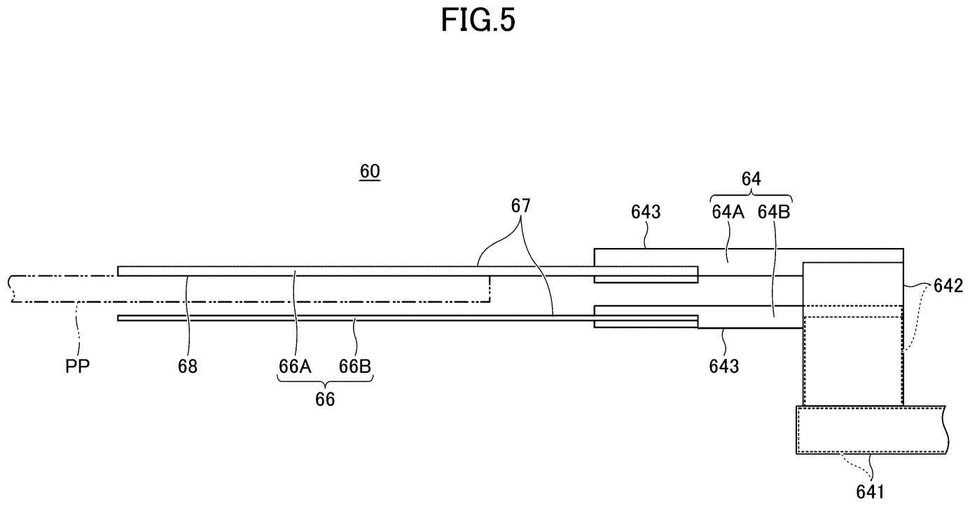

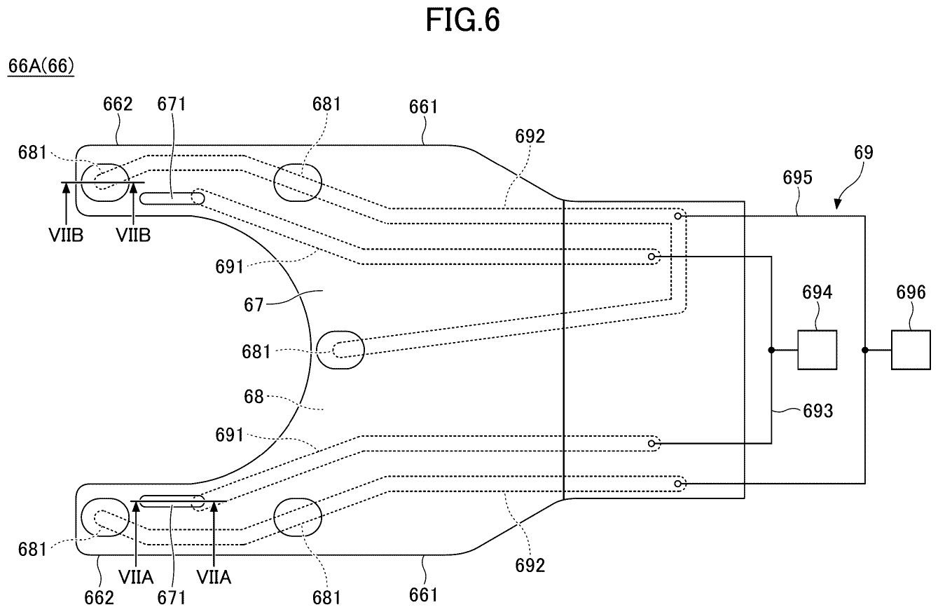

As illustrated in FIG. 6, the end effector 66 includes a base plate portion 661 fixed to the crank arm 643 (see FIG. 5), and a pair of fork plate portions 662 projecting from the base plate portion 661 toward the distal end. The base plate portion 661 and the pair of fork plate portions 662 are integrally formed, and the upper surfaces and lower surfaces of the base plate portion 661 and the pair of fork plate portions 662 are leveled and continuous in the horizontal direction. The inner edges of the pair of fork plate portions 662, which face each other, are curved and continuous via an arced edge at the distal end of the base plate portion 661. The shape of the end effector 66 is not particularly limited. For example, the end effector 66 may include three or more fork plate portions 662.

The transfer device 60 includes a suction mechanism 69 that causes each of a wafer W and a polishing member PP to be attracted to the first end effector 66A by suction. The transfer device 60 includes a suction mechanism (not illustrated) that causes only a wafer W to be adhered to the second end effector 66B by suction. Since the suction mechanism of the second end effector 66B is the same as the mechanism of the first end effector 66A to adhere a wafer W by suction, detailed description will be omitted.

The suction mechanism 69 independently applies suction pressure (negative pressure) to the first holder 67 and the second holder 68 of the first end effector 66A. In the present embodiment, the first holder 67 is configured by one or more (two) suction ports 671 formed in the upper surface of the first end effector 66A. The suction ports 671 are provided near the inner edges of the pair of fork plate portions 662, respectively.

The second holder 68 is configured by one or more (five) suction pads 681 formed on the lower surface of the first end effector 66A. Specifically, the five suction pads 681 are respectively provided at the distal ends of the pair of fork plate portions 662, linking portions between the base plate portion 661 and the pair of fork plate portions 662, and the distal end and center of the base plate portion 661. Since the suction pads 681 are provided the above positions of the base plate portion 661 and the pair of fork plate portions 662, a polishing member PP can be stably held.

The suction mechanism 69 includes first suction channels 691 respectively communicating with the suction ports 671, and second suction channels 692 respectively communicating with the suction pads 681 inside the first end effector 66A.

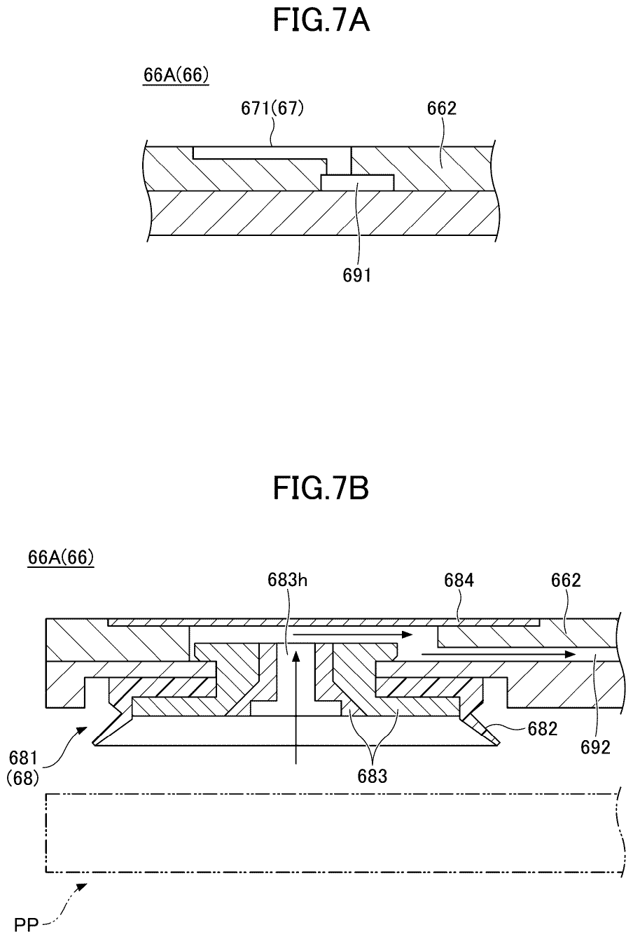

The suction port 671 has a long groove that longitudinally extends in the extending direction of the pair of fork plate portions 662. As illustrated in FIG. 7A, the suction port 671 communicates with one end (distal end) of the first suction channel 691 via a hole extending through the pair of fork plate portions 662 upward. Moreover, the suction port 671 is open along the flat upper surface of the first end effector 66A. Thus, the first end effector 66A can apply suction pressure while stably holding a wafer W with the entire upper surface of the first end effector 66A.

As illustrated in FIG. 7B, the suction pad 681 is slightly projected from the lower surface of the first end effector 66A, and the projected portion comes into contact with a polishing member PP and applies suction pressure to the polishing member PP, thereby adhering and holding the polishing member PP by suction. For example, the suction pad 681 includes a pad main body 682 that comes directly into contact with a polishing member PP, a fixing member 683 with which the pad main body 682 is fixed to the end effector 66, and a closure member 684 that covers the upper side of the fixing member 683 to close off the second suction channel 692.

The pad main body 682 is formed into a tapered shape (an umbrella shape or a conical shape) whose diameter gradually increases from the flat upper portion to the lower portion. The fixing member 683 is configured by constituent parts that clamp the pad main body 682 and the end effector 66 from the upper side and the lower side. A hole 683h is formed in the central portion of the fixing member 683. The closure member 684 closes the upper surface side of the end effector 66 after attaching the fixing member 683, thereby airtightly closing the second suction channel 692 that is open at the time of attaching the fixing member 683.

The second suction channel 692 extends inside the end effector 66 along an appropriate path, and one end of the second suction channel 692 extends and follows around the upper end (the closure member 684 side) of the fixing member 683 to communicate with the hole 683h. The end effector 66 applies suction pressure to the inside of the pad main body 682 through the second suction channel 692 and the hole 683h to adhere the polishing member PP in contact with the pad main body 682 by suction.

Referring back to FIG. 6, each first suction channel 691 communicates with a first suction source 694 via a plurality of first suction paths 693 (including a tube disposed outside the transfer arm 64) provided inside the first transfer arm 64A. Similarly, each second suction channel 692 communicates with a second suction source 696 via a plurality of second suction paths 695 (including a tube disposed outside the transfer arm 64) provided inside the first transfer arm 64A. The first suction channels 691 (or the first suction paths 693) may be joined together at a midway position. Similarly, the second suction channels 692 (or the second suction paths 695) may be joined together at a midway position. FIG. 6 illustrates an example in which two second suction channels 692 are joined together inside the end effector 66. The second suction path 695 may be provided with a valve, which is capable of opening to the atmosphere under the control of the controller 90, and is configured to introduce a gas into the pad main body 682 when a polishing member PP is released.

The first suction source 694 and the second suction source 696 are provided to the base 63 of the transfer device 60 or the like. As an example, the second suction source 696 includes a pump, a pressure regulator, a valve, and the like, which are not illustrated. The second suction source 696 applies suction pressure, which is adjusted through the second suction paths 695, the second suction channels 692, and suction ports 671, to a wafer W placed on the upper surface of the first end effector 66A.

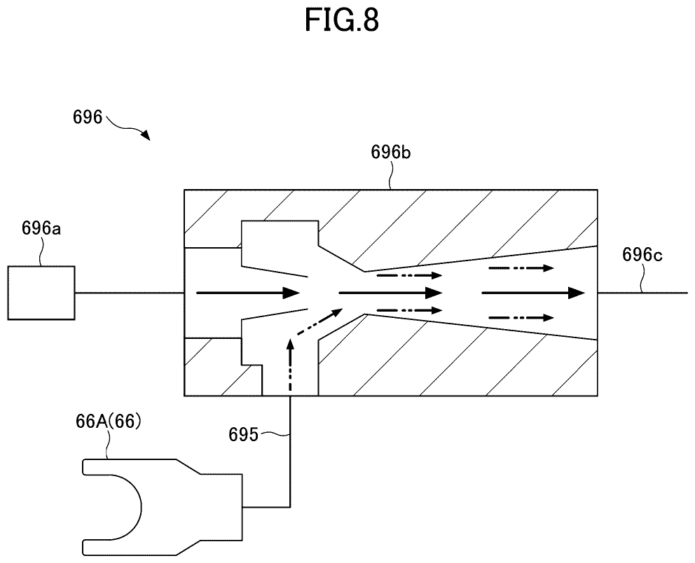

As illustrated in FIG. 8, the first suction source 694 includes a blower 696a, an ejection mechanism 696b, and an exhaust path 696c for applying suction pressure to the suction pads 681. The blower 696a supplies compressed air to the ejection mechanism 696b. As described above, the first holder 67 and the second holder 68 are configured by different suction lines. Specifically, the first holder 67 is configured by a vacuum suction line, and the second holder 68 is configured by a different suction line using air. Therefore, the first holder 67 and the second holder 68 can be independently controlled, and can be easily controlled to a desired pressure.

The ejection mechanism 696b is coupled to the blower 696a and the exhaust path 696c, and is also coupled to the first suction path 693 communicating with the first suction channel 691. Inside the ejection mechanism 696b, a main flow channel and a sub flow channel are provided. The main flow channel has an orifice at an intermediate point, where the diameter of the orifice gradually decreases relative to the diameter of the opening. The sub flow channel is joined at the orifice. The blower 696a is coupled to the upstream port of the main flow channel via an air supply path (not illustrated). The exhaust path 696c communicates with the downstream port of the main flow channel. The first suction path 693 communicates with the sub port of the sub flow channel. The ejection mechanism 696b configured as described above accelerates the flow rate of the compressed air, which is supplied from the air supply path 696d to the main flow channel, at the orifice, while directing the compressed air toward the exhaust path 696c, thereby generating a large negative pressure in the sub flow channel. Thus, the ejection mechanism 696b can apply suction pressure to each of the suction pads 681 via the first suction paths 693 communicating with the sub flow channel and the first suction flow channels 691. In FIG. 7B, the second holder 68 may have a function of removing particles with the air, and a function of removing polishing particles by vacuum. For example, the ejection mechanism 696b may be configured to switch between ejection of the compressed air from the pad main body 682 to remove the particles on the polishing member PP, and generation of suction pressure in a state in which the ejection mechanism 696b is set apart from the polishing member PP to suction the floating particles.

As illustrated in FIG. 3, the above transfer device 60 allows the base 63 to rotate about the rotation shaft of the rotation drive 62 as a base point according to a command from the controller 90, thereby setting the reciprocating direction of each of the transfer arms 64. For example, the transfer device 60 directs each end effector 66 in the direction (Y-axis negative direction) toward FOUP 29. Thus, each end effector 66 can advance in the Y-axis negative direction to access FOUP 29, and can retreat in the Y-axis positive direction back from FOUP 29 to the standby position. Moreover, the transfer device 60 directs each end effector 66 toward the direction (Y-axis positive direction) facing the polishing member standby region 23. Thus, the first end effector 66A can advances in the Y-axis positive direction to access the polishing member storage container 70, and can retreat in the Y-axis negative direction from the polishing member storage container 70 to the standby position.

Further, the transfer device 60 directs each end effector 66 in the direction (the X-axis positive direction) toward the inspection main body 10. Thus, each end effector 66 can advance in the X-axis positive direction to access the substrate support unit 40 or the polishing-member support unit 50, and can retreat in the X-axis negative direction from the substrate support unit 40 of the polishing-member support unit 50 to the standby position. Specifically, during loading and unloading of a wafer W, the controller 90 causes the moving device 41 to move the substrate support unit 40 in the horizontal direction (e.g., Y-axis direction), thereby arranging the mounting surface 45s below the gateway location to which each end effector 66 advances. Moreover, during loading and unloading of a polishing member PP, the controller 90 causes the moving device 41 to move the polishing-member support unit 50 in the horizontal direction (e.g., Y-axis direction), thereby arranging the support surface 52s below the gateway location to which each end effector 66 advances.

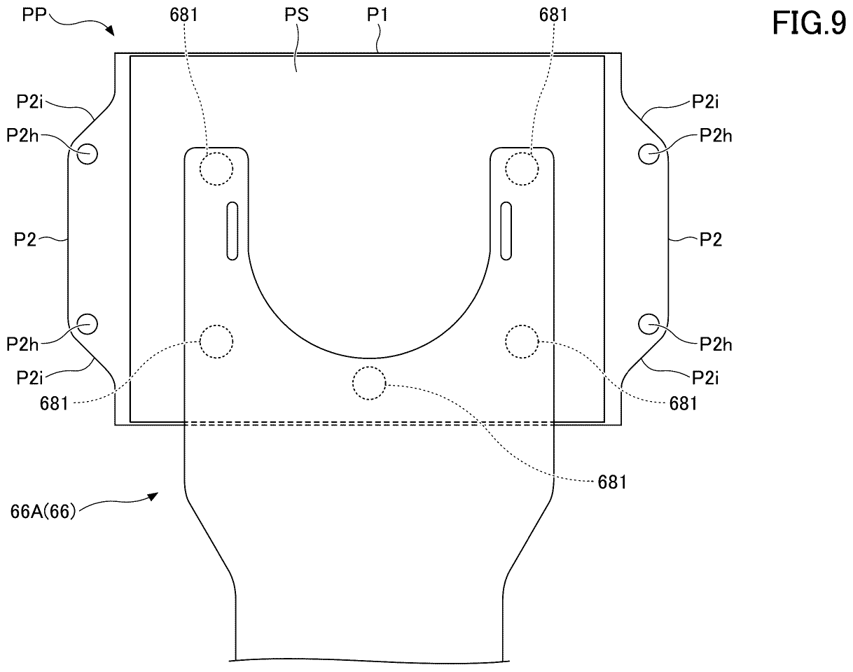

As illustrated in FIG. 9, at the time of transferring of the polishing member PP, the first end effector 66A adheres and holds the center portion of the polishing member PP by suction using the suction pads 681. The polishing member PP has a set thickness, and is formed into a rectangular shape having a smaller size than the size of the support surface 52s (see FIG. 3) of the polishing-member support unit 50 in a plan view.

More specifically, the polishing member PP includes a polishing plate P1, and a pair of positioning projections P2 provided on both ends of the polishing plate P1 in the longitudinal direction, respectively. A polishing sheet for polishing the contact probes 33 is adhered to the upper surface (one surface) of the polishing plate P1. The polishing sheet PS is formed into a rectangular shape that is slightly smaller than the polishing plate P1.

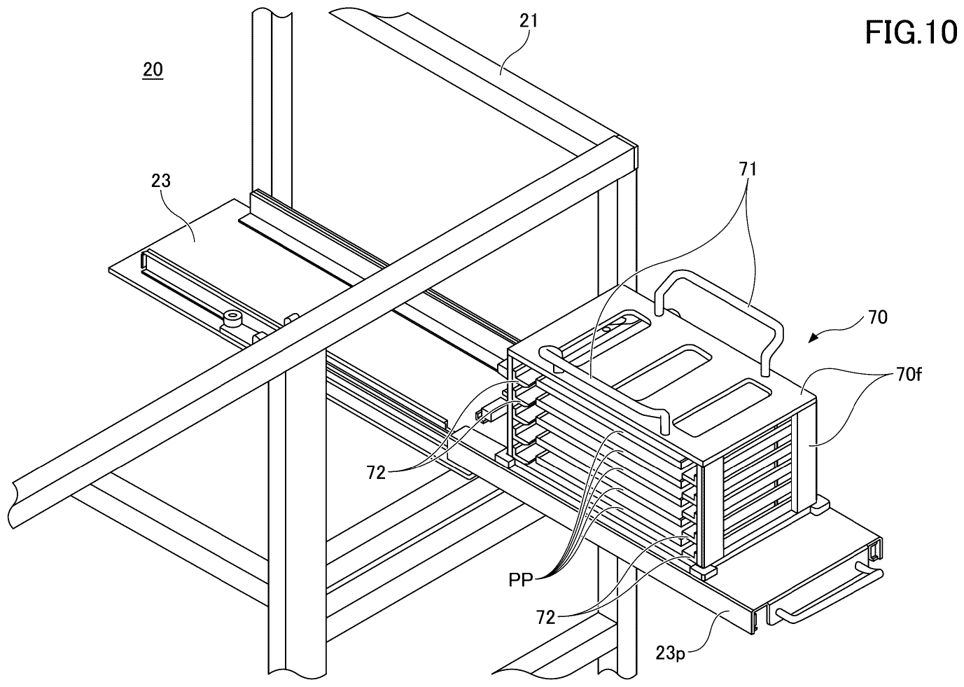

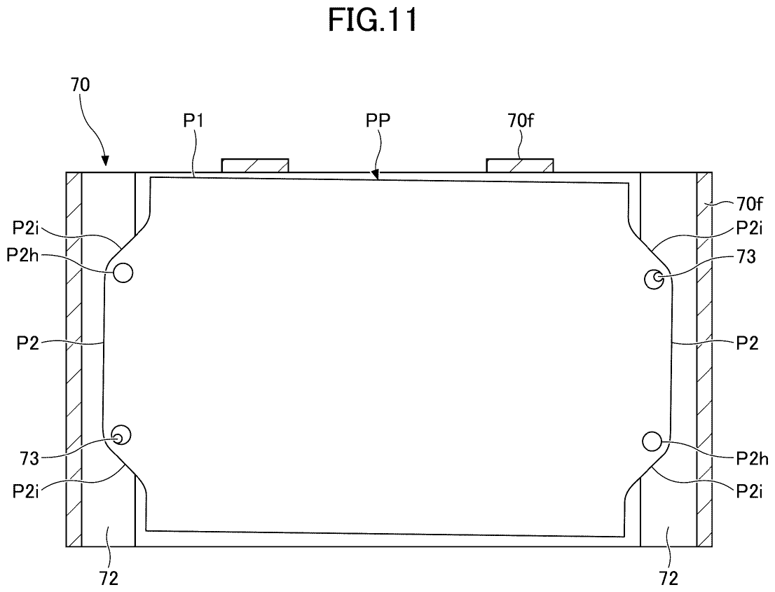

Each positioning projection P2 is formed into a trapezoidal shape continuous with a corresponding short side of the polishing plate P1 in a plan view. The linking portion between the polishing plate P1 and each of the positioning projections P2 is smoothly curved. One or more positioning holes P2h are provided in each positioning projection P2. Into the one or more positioning holes P2h, positioning pins (not illustrated), which are provided to the support surface 52s of the polishing-member support unit 50, or positioning pins 73 (see FIG. 11), which are provided to the polishing member storage container 70, are inserted at the time of transferring a polishing member PP.

As illustrated in FIG. 10, the polishing member storage container 70 is formed into a substantially cuboid shape in which multiple (5 sheets of) polishing members PP are stored in the vertical direction. It is needless to say that the number of polishing members PP stored in the polishing member storage container 70 is not particularly limited. The polishing member storage container 70 has a frame structure constructed by assembling a plurality of frames 70f. The side surface of the frame structure on the Y-axis negative direction side facing the transfer device 60 is open. Grip bars 71, with which a user can grip the polishing member storage container 70, are provided on the outer side of the polishing member storage container 70.

A plurality of inner shelf plates 72 are provided on both inner sides of the polishing member storage container 70 in the longitudinal direction. The polishing member storage container 70 horizontally supports a polishing member PP with a pair of the inner shelf plates 72 positioned at the same height on both sides in the longitudinal direction. A gap between the inner shelf plates 72 in the vertical direction is set to be greater than a total thickness of the first end effector 66A and the polishing member PP so that the first end effector 66A can enter the gap.

The polishing member standby region 23 of the loader 20 is configured so that the polishing member storage container 70 can be pulled out in the X-axis negative direction. The polishing member standby region 23 has a mounting plate 23p on which the polishing member storage container 70 is mounted. The mounting plate is slidable in the X-axis direction. Thus, a user pulls out the mounting plate and the polishing member storage container 70 outside the loader 20 so that the polishing member storage container 70 itself can be replaced (or polishing members PP inside the polishing member storage container 70 can be replaced).

As illustrated in FIG. 11, the positioning pins 73 are inserted into the positioning holes P2h in the state in which the polishing member PP is supported by a pair of the inner shelf plates 72 of the polishing member storage container 70 so that the polishing member PP is positioned. Thus, the polishing member PP is held in a manner such that the outer edges of the polishing member PP are substantially parallel to the frame of the polishing member storage container 70.

The positioning holes P2h are formed to be larger than the positioning pins 73, and therefore there is a case where a polishing member PP is stored with a slight inclination (e.g., approximately 1°) with respect to a reference standby position of the polishing member storage container 70. As illustrated in FIG. 3, moreover, the inspection device 1 transfers a rectangular polishing member PP to the support surface 52s of the polishing-member support unit 50 in the X-axis direction. Therefore, the longitudinal direction of the polishing member PP needs to be aligned with the X-axis direction when the polishing member PP enters the inspection main body 10. Thus, the loader 20 includes a position adjustment device 80 in the position adjustment region 25. The position adjustment device 80 adjusts a horizontal position, which is the position of the polishing member PP in the horizontal direction (the X-Y-axis direction).

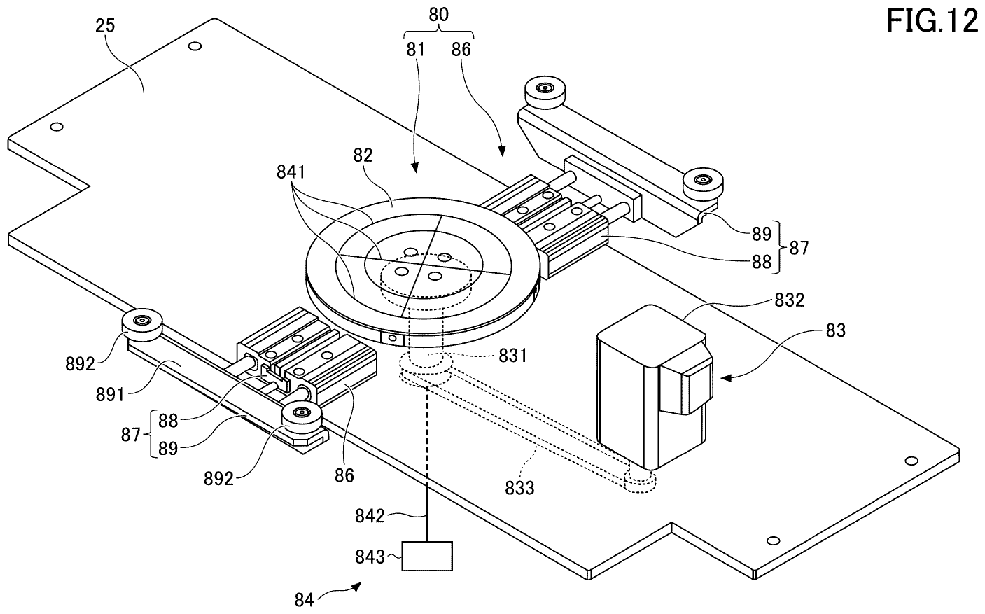

As illustrated in FIG. 12, the position adjustment device 80 includes a turning mechanism 81 that adjusts the orientation of the polishing member PP in the rotational direction, and a clamp mechanism 86 that clamps the polishing member PP to perform centering. Specifically, the “adjustment of the horizontal position” of the polishing member PP refers to the definition of a position in a rotational direction about a vertical axis with the center of the polishing member PP serving as a base point, positioning (centering) of the polishing member PP with the center of the polishing member PP as a reference, or both.

The turning mechanism 81 rotates the polishing member PP, which has been transferred by the transfer device 60, about the vertical axis. The turning mechanism 81 includes a table 82 on which a polishing member PP is placed, a turning drive 83 that turns the table 82, and a turning mechanism-side suction device 84 that adheres the polishing member PP placed on the table 82 by suction.

The table 82 is a circular plate having a perfect circular shape in a plan view, and is disposed at a center of the position adjustment region 25. The table 82 is formed to have a flat upper surface. Moreover, the table 82 has a suction groove 841 for adhering the lower surface of the polishing member PP by suction.

The turning drive 83 includes a rotation shaft 831 that supports the center of the table 82, a motor 832 that generates a rotational drive force, and a rotation transmission 833 that transmits the rotational drive force of the motor 832 to the rotation shaft 831. For example, the rotation transmission 833 is configured by pulleys, gears, or the like between the rotation shaft 831 and the motor 832. The turning drive 83 rotates the table 82 by a set angle (e.g., 90°) according to the command of the controller 90.

The turning mechanism-side suction device 84 includes the suction groove 841 formed in the upper surface of the table 82 and a suction path 842 communicating with the suction groove 841 inside of the table 82. The suction path 842 extends to the outside of the position adjustment region 25 through the rotation shaft 831, and is coupled to a turning mechanism-side suction mechanism 843 disposed outside the position adjustment region 25. The turning mechanism-side suction mechanism 843 includes a suction pump, a flow rate regulator, an opening/closing valve, and the like. Thus, the turning mechanism-side suction mechanism 843 is operated according to the command of the controller 90 so that the turning mechanism-side suction device 84 can adhere the lower surface of the polishing member PP placed onto the table 82 by suction.

The clamp mechanism 86 includes slider moving portions 87 respectively disposed on both sides of the position adjustment region in the Y-axis direction with the table 82 of the turning mechanism 81 as a base point. Each of the slider moving portions 87 includes a fixed drive 88 fixed to the base of the position adjustment region 25, and a slider 89 that is allowed to advance or retreat by the fixed drive 88.

The fixed drive 88 includes a drive source, such as an air cylinder mechanism or the like, inside the fixed drive 88, and bars projecting outward in the Y-axis direction to be linked with the slider 89. Each slider moving portions 87 is arranged such that the bars and the slider 89 extend in opposite directions to each other in the X-axis direction. The fixed drive 88 causes the bars and the slider 89 to advance or retreat, when the drive source is operated according to the command of the controller 90. Thus, the pair of sliders 89 can move in the direction approaching each other or in the direction moving away from each other.

Each of the sliders 89 includes a frame 891 that is long in the X-axis direction, and a pair of contact rollers 892 respectively provided on both ends of the frame 891 in the longitudinal direction (X-axis direction). The contact rollers 892 on each slider 89 is set apart from each other by a gap corresponding to the size of the positioning projection P2 of the polishing member PP, and are supported to be rotatable relative to the frame 891. Each of the contact rollers 892 comes into contact with a corresponding inclined portion of the positioning projection P2 when the sliders 89 approach each other.

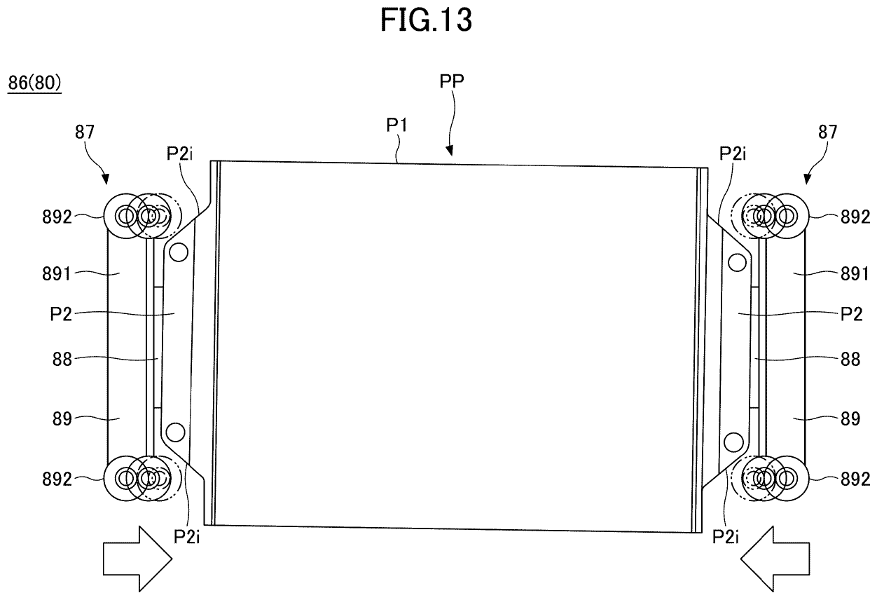

As illustrated in FIG. 13, the clamp mechanism 86 configured as described above can clamp both edges of the polishing member PP placed on the table 82 in the longitudinal direction with the pair of sliders 89 when the pair of sliders 89 approach each other. When the pair of sliders 89 approach each other, the contact rollers 892 initially come into contact with the corresponding inclined portions P2i of the positioning projection P2 to guide the positioning projections P2 of the polishing member PP between the contact rollers 892. As the pair of sliders 89 clamp (approach), the clamp mechanism 86 can perform centering to match the center of the polishing member PP with the center of the table 82. In the case where the polishing member PP placed on the table 82 is slightly inclined, moreover, the clamp mechanism 86 can guide the inclined portions P2i with the corresponding contact rollers 892 so that fine adjustment of the position of the polishing member PP can be desirably performed.

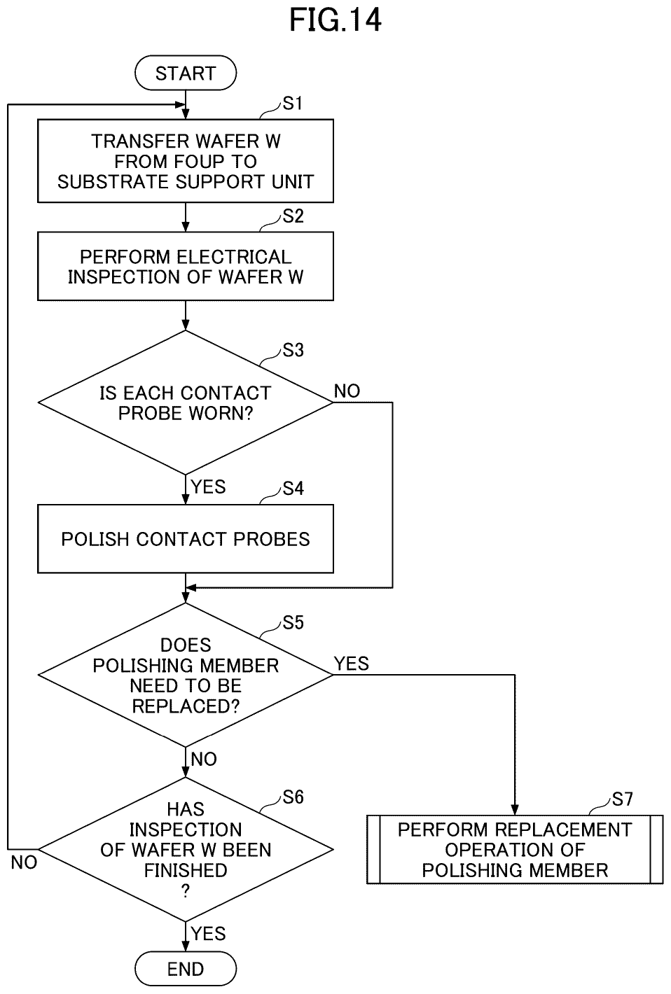

The inspection device 1 and the loader 20 according to the present embodiment are basically configured as described above. The operation of the inspection device 1 (transfer method) will be described with reference to FIGS. 14 to 19.

The controller 90 of the inspection device 1 causes the transfer device 60 of the loader 20 to transfer wafers W and polishing members PP. As illustrated in FIG. 14, the controller 90 performs a substrate loading action in which a wafer W is transferred from FOUP 29 to the substrate support unit 40 by the first end effector 66A of the transfer device 60 for inspection of the wafer W (step S1). At the above step, the controller 90 performs control of adhering the wafer W on the first holder 67, which is provided on the upper surface of the first end effector 66A, by suction to transfer the wafer W. In the case where there is the inspected wafer W on the substrate support unit 40 at the time of transferring the wafer W for inspection, the controller 90 performs a support unloading action in which, for example, the inspected wafer W is unloaded from the substrate support unit 40 by the second end effector 66B.

Thereafter, the controller 90 performs control of moving the moving device 41 to bring the wafer W, which has been transferred to the substrate support unit 40, into contact with the contact probes 33 of the tester 30 (probe card 32), thereby performing an electrical inspection of inspection target devices on the wafer W (step S2).

During the inspection of the wafer W, or at the time of maintenance of the inspection device 1, or the like, the controller 90 determines the state (abrasion and the like) of each of the contact probes 33 (step S3). Then, in the case where the contact probes 33 are worn out (step S3: YES), step S4 is performed. In the case where the contact probes 33 are not worn (step S3: NO), step S4 is omitted, and the process proceeds to step S5.

At step S4, the controller 90 performs control of, after unloading the wafer W from the inspection main body 10, moving the polishing-member support unit 50 with the moving device 41 to bring the polishing member PP into contact with the contact probes 33, thereby polishing the contact probes 33. For example, during the polishing, the polishing-member support unit 50 allows the polishing member PP to advance or retreat along the set path in the horizontal direction using the moving device 41, thereby polishing the contact probes 33.

Further, the controller 90 continuously monitors trigger conditions for replacing the polishing member PP during the operation of the inspection device 1, and determines whether the polishing member PP needs to be replaced or not (step S5). For example, as the trigger conditions, the number of times polishing performed on the contact probes 33 of the probe card 32 with the polishing member PP set on the polishing-member support unit 50 is counted, and whether or not the number of times polishing performed reaches a set number or higher is determined. Specifically, in the case where the number of times polishing performed reaches the set number or higher, it is considered that the polishing member PP needs to be replaced. In the case where the number of times polishing performed is lower than the set number, it is considered that replacement of the polishing member PP is unnecessary. Moreover, as the trigger conditions, usage duration of the polishing member PP in the polishing-member support unit 50 is measured, and whether or not the usage duration of the polishing member PP reaches a set period or longer may be determined, or a replacement instruction may be received from a user via the user interface 95.

Once the controller 90 determines that the replacement of the polishing member PP is unnecessary (step S5: NO), the controller 90 performs step S6. At step S6, the controller 90 determines whether or not the inspection of the wafer W is ended. In the case where the inspection of the wafer W is continued (step S6: NO), the process returns back to step S1, and the subsequent steps are repeated in the same manner. In the case where the inspection of the wafer W is ended (step S6: YES), the process flow is ended.

Once the controller 90 determines the replacement of the polishing member PP is necessary at step S5 (step S5: YES), the process proceeds to the polishing member PP replacement operation (step S7). In the polishing member PP replacement operation, first, a polishing member loading action is performed. In the polishing member loading action, the used polishing member PP held on the polishing-member support unit 50 of the inspection main body 10 is transferred to the polishing member storage container 70 of the loader 20.

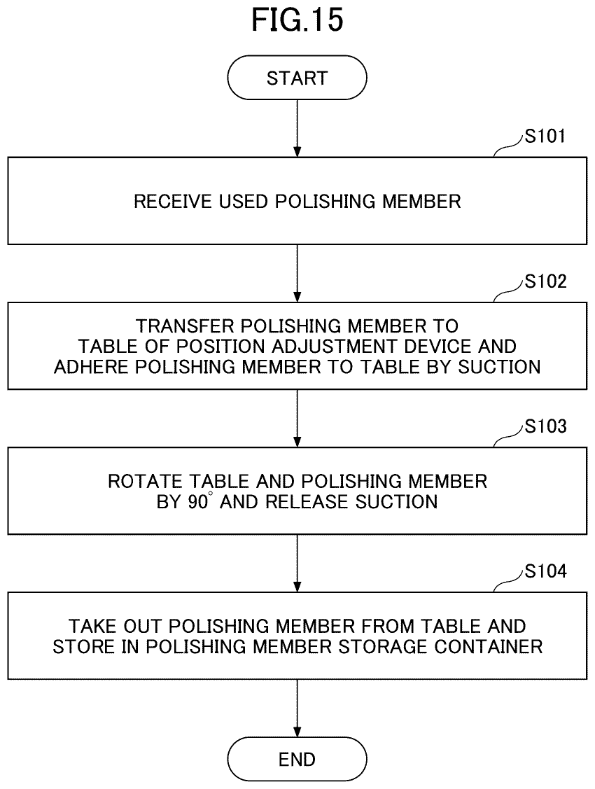

Specifically, the controller 90 performs the polishing member unloading action according to the steps of the process flow illustrated in FIG. 15.

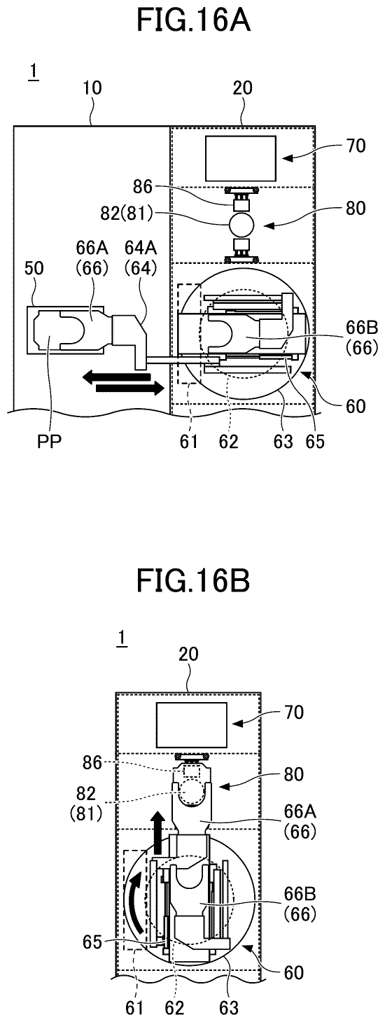

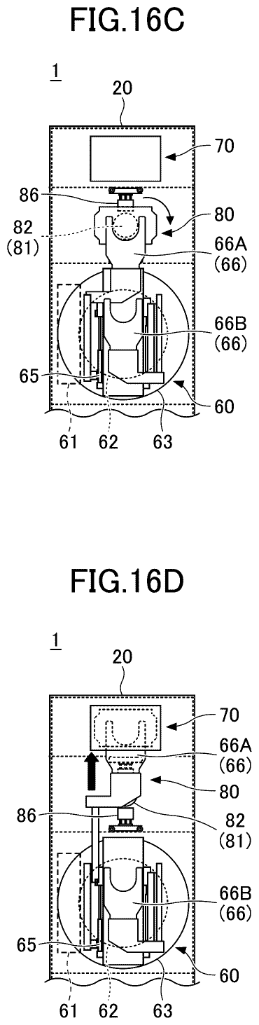

First, the controller 90 causes the first end effector 66A of the transfer device 60 to receive the used polishing member PP placed on the polishing-member support unit 50 (step S101). When receiving the used polishing member PP, as illustrated in FIG. 16A, the controller 90 performs control of operating the moving device 41 of the inspection main body 10 first. The moving device 41 moves the polishing-member support unit 50 to arrange the polishing member PP below the gateway location to which the first end effector 66A advances.

Then, the controller 90 causes the transfer device 60 to receive the polishing member PP using the first end effector 66A. Specifically, the transfer device 60 allows the first transfer arm 64A, which is waiting at a standby position, to move forward using the reciprocation drive 65 so that the first end effector 66A faces the polishing member PP placed on the polishing-member support unit 50. Next, the transfer device 60 allows the first end effector 66A to lower or lift the polishing member support unit 50 using the lifting drive 61 to bring the suction pads 681 into contact with the upper surface of the polishing member PP. Then, the transfer device 60 allows the suction mechanism 69 to apply suction pressure from the suction pads 681 to the polishing member PP, thereby adhering the polishing member PP by suction. After receiving the polishing member PP on the polishing-member support unit 50 with the first end effector 66A, the longitudinal direction (reciprocating direction) of the first end effector 66A and the longitudinal direction of the polishing member PP are parallel to each other.

Next, the transfer device 60 transfers the polishing member PP held by the first end effector 66A to the position adjustment device 80 in the position adjustment region 25 (step S102 of FIG. 15). As illustrated in FIG. 16B, the transfer device 60 allows the first end effector 66A to move in the X-axis negative direction (from the gateway location to the standby position) using the reciprocation drive 65. Then, the transfer device 60 rotates the base 63 and the first transfer arm 64A (first end effector 66A) by 90° in the clockwise direction using the rotation drive 62. Thus, the first end effector 66A can advance in the Y-axis positive direction (polishing member standby region 23).

The longitudinal direction of the polishing member PP held by the first end effector 66A is parallel to the reciprocating direction of the first end effector 66A, and is perpendicular to the longitudinal direction of the polishing member storage container 70 (is not matched with a storage position in the polishing member storage container 70). Thus, the controller 90 causes the position adjustment device 80 to rotate the horizontal position of the polishing member PP by 90° in the clockwise or anticlockwise direction.

The transfer device 60 allows the first end effector 66A to advance to the position facing the table 82 of the position adjustment device 80 using the reciprocation drive 65, and allows the first end effector 66A to be lowered using the lifting drive 61, thereby placing the polishing member PP on the table 82. In this state, the controller 90 performs control of releasing the suction of the suction pads 681 of the first end effector 66A, and operating the turning mechanism-side suction device 84 to adhere the polishing member PP to the table 82 by suction. After adhering the polishing member PP to the table 82 by suction, the transfer device 60 allows the first end effector 66A to be lifted from the polishing member PP using the lifting drive 61.

In the state in which the polishing member PP is adhered to the table 82 by suction, the position adjustment device 80 rotates the table 82 and the polishing member PP by 90° using the turning drive 83, followed by releasing the suction of the polishing member PP to the table 82 (step S103 of FIG. 15). Thus, on the table 82 of the position adjustment device 80, the longitudinal direction of the polishing member PP and the longitudinal direction of the polishing member storage container 70 are substantially parallel to each other, as illustrated in FIG. 16C.

Therefore, the controller 90 causes the first end effector 66A of the transfer device 60 to take out the polishing member PP whose horizontal position has been adjusted from the table 82 and to store the polishing member PP in the polishing member storage container 70 (step S104 of FIG. 15). During this operation, the transfer device 60 allows the first end effector 66A to be lowered using the lifting drive 61 to bring the suction pads 681 into contact with the upper surface of the polishing member PP, and causes the polishing member PP to be adhered to the suction pads 681 by suction using the suction mechanism 69. Further, the transfer device 60 adjusts the positions of the first end effector 66A and the polishing member PP in the vertical direction using the lifting device 61 to match with the height of the space (a pair of the inner shelf plates 72) to which the polishing member PP is stored in the polishing member storage container 70.

Then, as illustrated in FIG. 16D, the transfer device 60 allows the first end effector 66A to move forward using the reciprocation drive 65, thereby moving the polishing member PP into the polishing member storage container 70. In the state in which the polishing member PP faces a pair of inner shelf plates 72, the transfer device 60 lowers the first end effector 66A, and releases the polishing member PP at the designated position.

According to the above process flow, the inspection device 1, the loader 20, and the transfer method can smoothly transfer the polishing member PP from the polishing-member support unit 50 to the polishing member storage container 70. In particular, in the inspection device 1, the horizontal position of the polishing member PP is adjusted before being stored in the polishing member storage container 70 by the position adjustment device 80 disposed between the transfer device 60 and the polishing member storage container 70 (on the transfer path of the polishing member PP). Thus, the polishing member PP can be accurately stored in the polishing member storage container 70 within a short period.

Next, a polishing member loading action in the polishing member PP replacement operation, which is performed after the polishing member unloading action, will be described. In the polishing member loading action, the controller 90 causes the transfer device 60 to transfer a replacing polishing member PP, which is put on standby in the polishing member storage container 70, to the polishing-member support unit 50. In the case where a polishing member PP is not set in the polishing-member support unit 50, it is needless to say that the polishing member loading action can be performed without performing the polishing member unloading action.

The controller 90 manages the state and position of each of polishing members PP in the polishing member storage container 70 in advance, and appropriately selects a replacing polishing member PP before the polishing member loading action (e.g., when the trigger conditions for replacement have been satisfied). The replacing polishing member PP may be an unused (new) polishing member PP or a used polishing member PP that has not been worn much.

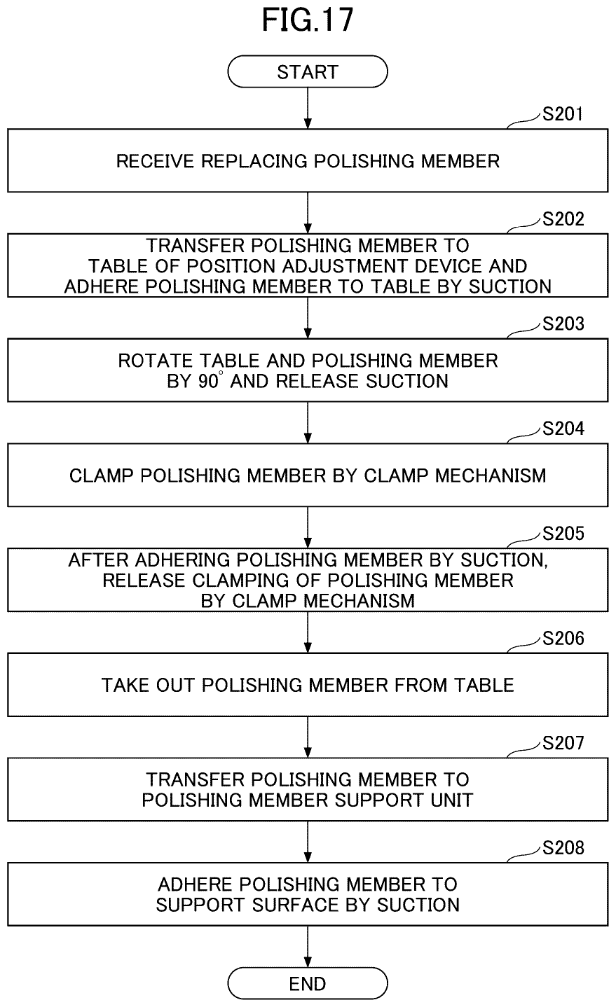

Specifically, the controller 90 performs the polishing member loading action according to the steps of the process flow illustrated in FIG. 17.

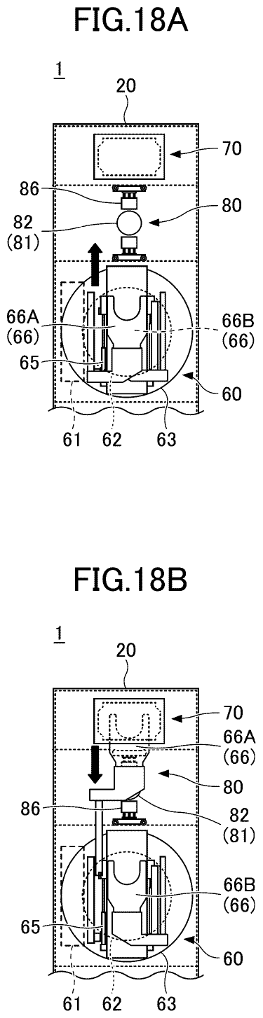

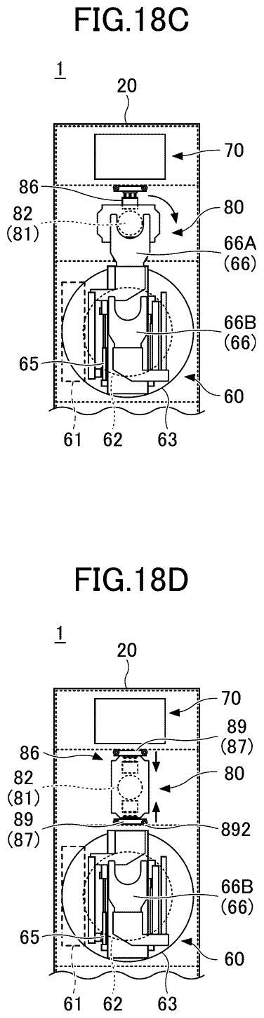

The controller 90 performs control of receiving a specified replacing polishing member PP in the polishing member storage container 70 using the first end effector 66A of the transfer device 60 (step S201). As illustrated in FIG. 18A, the transfer device 60 allows the first end effector 66A to advance using the reciprocation drive 65, thereby moving the first end effector 66A into the space above the replacing polishing member PP in the polishing member storage container 70. In the case where the used polishing member PP is stored in the polishing member storage container 70 first, the first end effector 66A is slightly withdrawn from the polishing member storage container 70, and then the height of the first end effector 66A can be adjusted to insert the first end effector 66A back into the polishing member storage container 70.

Next, the transfer device 60 allows the first end effector 66A to be lowered using the lifting drive 61, thereby bringing the suction pads 681 into contact with the upper surface of the polishing member PP. Further, the transfer device 60 operates the suction mechanism 69 to apply suction pressure to the polishing member PP from the suction pads 681, thereby adhering the polishing member PP by suction. After receiving the polishing member PP with the first end effector 66A, the longitudinal direction (reciprocating direction) of the first end effector 66A and the longitudinal direction of the polishing member PP are perpendicular to each other. Therefore, the controller 90 causes the position adjustment device 80 to rotate the horizontal position of the polishing member PP by 90° in the clockwise direction (or the anticlockwise direction).

The transfer device 60 transfers the polishing member PP held with the first end effector 66A to the table 82 of the position adjustment device 80 (step S202 of FIG. 17). As illustrated in FIG. 18B, the transfer device 60 allows the first end effector 66A to retreat in the Y-axis negative direction using the reciprocation drive 65 so that the first end effector 66A arranges the polishing member PP, which is held with the first end effector 66A, to face the table 82 located on the transfer path of the polishing member PP. Then, the transfer device 60 lowers the first end effector 66A using the lifting drive 61 to place the polishing member PP on the table 82. In this state, the controller 90 releases the suction of the first end effector 66A by the suction pads 681, and operates the turning mechanism-side suction device 84 to adhere the polishing member PP to the table 82 by suction. After adhering the polishing member PP to the table 82 by suction, the transfer device 60 allows the first end effector 66A to be lifted from the polishing member PP using the lifting drive 61.

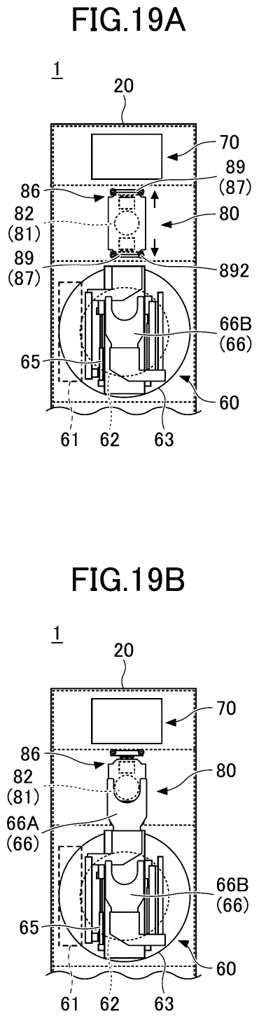

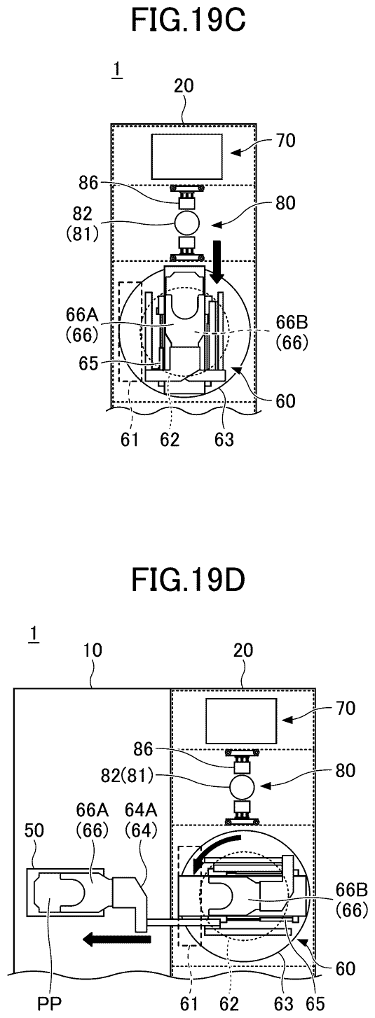

In the state in which the polishing member PP is adhered to the table 82 by suction, the position adjustment device 80 allows the table 82 to be rotated by 90° in the clockwise direction (or the anticlockwise direction) using the turning drive 83, followed by releasing the suction for the polishing member PP to be adhered to the table 82 (step S203 of FIG. 17). Thus, as illustrated in FIGS. 18C and 18D, the polishing member PP is also rotated by 90°. The position adjustment device 80 can arrange the orientation of the polishing member PP so that the longitudinal direction of the polishing member PP and the longitudinal direction (reciprocating direction) of the first end effector 66A are substantially parallel to each other above the table 82. In FIGS. 18D and 19A, illustration of the first end effector 66A is omitted so that the operation of the position adjustment device 80 is easily understood.

Next, the position adjustment device 80 is operated to clamp the polishing member PP with the clamp mechanism 86, thereby finely adjusting the horizontal position of the polishing member PP (S204 of FIG. 17). As illustrated in FIG. 18D, the position adjustment device 80 allows a pair of sliders 89 to move in the direction approaching each other to clamp the polishing member PP in the longitudinal direction. Thus, the center of the polishing member PP matches with the center of the table 82, and the longitudinal direction of the polishing member PP and the reciprocating direction of the first end effector 66A are finely adjusted to be parallel to each other (also see FIG. 13).

In the state in which the polishing member PP is clamped by the clamp mechanism 86, the position adjustment device 80 allows the polishing member PP to be adhered onto the upper surface of the table 82 by suction using the turning mechanism-side suction device 84, followed by releasing clamping of the polishing member PP by the clamp mechanism 86 (step S205 of FIG. 17). Specifically, as illustrated in FIG. 19A, the position adjustment device 80 moves the pair of the sliders 89 in the direction moving away from each other. Thus, the position adjustment device 80 is in the state in which the polishing member PP whose horizontal position is adjusted to correspond to the polishing-member support unit 50 is held on the table 82.

Then, the controller 90 causes the transfer device 60 to take out the polishing member PP whose horizontal position has been adjusted using the first end effector 66A (step S206 of FIG. 17). As illustrated in FIG. 19B, the transfer device 60 allows the first end effector 66A to be lowered using the lifting drive 61 to bring the suction pads 681 into contact with the upper surface of the polishing member PP, thereby allowing the polishing member PP to be adhered to the suction pads 681 by suction using the suction mechanism 69. The position adjustment device 80 operates the turning mechanism-side suction device 84 to release the suction for the polishing member PP to the table 82. Thus, the transfer device 60 can allow the polishing member PP to be floated off the table 82 without shifting the position, when the first end effector 66A is lifted by the lifting drive 61.

Then, the transfer device 60 loads the polishing member PP, which is held by the first end effector 66A, onto the polishing-member support unit 50 of the inspection main body 10 (step S207 of FIG. 17). During this operation, as illustrated in FIG. 19C, the transfer device 60 allows the first end effector 66A to move in the Y-axis negative direction (toward the standby position) using the reciprocation drive 65. Thereafter, as illustrated in FIG. 19D, the transfer device 60 rotates the base 63 and the first transfer arm 64A (first end effector 66A) by 90° in the anticlockwise direction using the rotation drive 62. Thus, the first end effector 66A can advance in the X-axis positive direction (toward the gateway location in the inspection main body 10).

In the inspection main body 10, the moving device 41 moves the polishing-member support unit 50 to be put on standby below the gateway location. Therefore, the transfer device 60 lowers the first end effector 66A with the lifting device 61 after allowing the first end effector 66A to advance using the reciprocation drive 65. Thus, the polishing member PP can be accurately placed on the support surface 52s of the polishing-member support unit 50. After transferring the polishing member PP immediately above the polishing-member support unit 50, the controller 90 may cause the polishing-member support unit 50 to be lifted to reduce the gap with the polishing member PP, thereby passing the polishing member PP from the first end effector 66A to the polishing-member support unit 50. Alternatively, the controller 90 may cause both the polishing-member support unit 50 and the first end effector 66A to operate to pass the polishing member PP.

After placing the polishing member PP on the polishing-member support unit 50, the controller 90 may cause the unit-side suction device 54 of the polishing-member support unit 50 to generate suction force to adhere the polishing member PP to the support surface 52s (step S208 of FIG. 17). Thus, in the inspection device 1, the replacing polishing member PP can be automatically set on the polishing-member support unit 50. Then, the inspection device 1 can polish the contact probes 33 of the probe card 32 with the polishing member PP.

At an appropriate timing during the inspection of the wafer W, the inspection device 1 can perform the above transfer method (polishing member loading action and polishing member unloading action). In the inspection device 1, a single polishing member PP is held and transferred by the first end effector 66A. Alternatively, in the inspection device 1, the above transfer method may be performed in the state in which a wafer W is held on the upper surface of the first end effector 66A, and a polishing member PP is held on the lower surface of the first end effector 66A.

The inspection device 1, the loader 20, and the transfer method are not limited to the above embodiments, and various modifications can be made. For example, although the horizontal position of the polishing member PP is adjusted by the position adjustment device 80 in the above embodiment, the inspection device 1 may be configured such that the polishing member PP is transferred to the polishing-member support unit 50 without passing through the position adjustment device 80. In one example, positions of polishing members PP stored in the polishing member storage container 70 are adjusted (for example, polishing members PP are stored to align the longitudinal direction of each polishing member PP with the Y-axis direction in FIG. 3) according to transfer paths of the polishing-member support unit 50 and the transfer device 60. Thus, the transfer device 60 can perform placement of a polishing member PP in a state in which the longitudinal direction of the support surface 52s of the polishing-member support unit 50 and the longitudinal direction of the polishing member PP are matched even when the polishing member PP is transferred without rotating.

Moreover, the first end effector 66A according to the above embodiment has a configuration in which the first holder 67 for holding a wafer W is disposed on the upper surface of the first end effector 66A, and the second holder 68 for holding a polishing member PP is disposed on the lower surface of the first end effector 66A. However, the first end effector 66A may have a configuration in which the first holder 67 is disposed on the lower surface, and the second holder 68 is disposed on the upper surface. In this case, the suction pads 681 can be provided to the first holder 67 on the lower surface side.

In the loader 20, FOUP 29, the transfer device 60, and the polishing member storage container 70 are arranged to parallel to the longitudinal direction of the inspection main body 10 in a plan view. However, the arrangement is not limited to the above. For example, the loader 20 may have a configuration in which FOUP 29 and the polishing member storage container 70 are arranged to overlap each other in the vertical direction.

The technical concepts and effects of the present disclosure, which have been described through the above embodiments, will be described hereinafter.

The inspection device 1 according to the first embodiment of the present disclosure includes a first stage (substrate support unit 40) that supports a substrate (wafer W) to be in contact with one or more contact probes 33, a second stage (polishing-member support unit 50) that is disposed in a vicinity of the first stage, and supports a polishing member PP capable of polishing the one or more contact probes 33, a substrate storage (FOUP 29) that stores one or more substrates including the substrate, a polishing member storage (polishing member storage container 70) that stores one or more polishing members PP including the polishing member PP, and a transfer device 60 including a transfer arm 64 that transfers the substrate between the first stage and the substrate storage, and transfers the polishing member PP between the second stage and the polishing member storage. The transfer arm 64 includes a first holder 67 capable of holding the substrate, and a second holder 68 capable of holding the polishing member at a different position from the first holder 67.

According to the above, the inspection device 1 can transfer each of a substrate (wafer W) and polishing member PP using the first holder 67 and the second holder 68 of the transfer arm 64. Thus, the inspection device 1 can automatically perform replacement of a polishing member PP, and reduces a workload of a user in association with the replacement of the polishing member PP, thereby increasing work efficiency.

Moreover, the transfer arm 64 includes an end effector 66 that is in a shape of a plate. The end effector 66 includes one or more suction ports 671 on an upper surface of an upper surface of the end effector 66. The one or more suction ports 671 constitute one of the first holder 67 or the second holder 68. The end effector 66 includes one or more suction pads 681 on a lower surface of the end effector 66. The one or more suction pads 681 constitute the other one of the first holder 67 and the second holder 68. Thus, in inspection device 1, the wafer W (or the polishing member PP) can be desirably held on the upper surface by the one or more suction ports 671, and the polishing member PP (or the wafer W) can be desirably held on the lower surface by the one or more suction pads 681.

Moreover, the end effector 66 includes an ejection mechanism 696b that applies suction pressure to the polishing member PP via the one or more suction pads 681 constituting the second holder 68. Thus, the inspection device 1 achieves further secure retention of the polishing member PP with the end effector 66.

Each of the one or more suction pads 681 includes a pad main body 682 to be in contact with the polishing member PP. The pad main body 682 has a tapered shape. The end effector 66 includes a suction channel (second suction channel 692) inside the end effector 66. The suction channel communicates with an inside of the pad main body 682 and is capable of applying suction pressure to the pad main body 682. Thus, the inspection device 1 can stably apply suction pressure to the inside of the pad main body 682 in contact with the polishing member PP, and can smoothly release the suction.

The end effector 66 includes a base plate portion 661, and a pair of fork plate portions 662 projected from the base plate portions 661. The suction pads 681 are provided to each of the base plate portion 661 and the pair of fork plate portions 662. Thus, the polishing member PP can be held by the entire end effector 66 so that the inspection device 1 can transfer the polishing member PP more stably.

The inspection device includes an inspection main body 10 including the first stage (substrate support unit 40) and the second stage (polishing-member support unit 50), and a loader 20 disposed in a vicinity of the inspection main body 10. The loader 20 includes the substrate storage (FOUP 29), the transfer device 60, and the polishing member storage (polishing member storage container 70) disposed in this order in a direction parallel to the inspection main body 10 in a plan view. Thus, the inspection device 1 realizes easy access to both the substrate storage and the polishing member storage owing to the transfer device 60.

The transfer device 60 includes a lifting drive 61 that lifts and lowers the transfer arm 64 in a vertical direction, a rotation drive 62 that rotates the transfer arm 64 about a vertical axis, and a reciprocation drive 65 that linearly moves the transfer arm 64 to reciprocate. Thus, the transfer device 60 can smoothly transfer the substrate (wafer W) and the polishing member PP within the loader 20, and between the loader 20 and the inspection main body 10.

The substrate storage (FOUP 29) stores a plurality of the substrates (wafers W) in the vertical direction, and the polishing member storage (polishing member storage container 70) stores a plurality of the polishing members PP in the vertical direction. The transfer device 60 adjusts a height of the transfer arm 64 with lifting and lowering of the lifting drive 61, adjusts a reciprocation direction of the transfer arm 64 with rotation of the rotation drive 62, and allows the transfer arm 64 to access the plurality of substrates of the substrate storage or the plurality of polishing members PP of the polishing member storage with a reciprocating movement of the reciprocation drive 65. Thus, the transfer device 60 can smoothly transfer the wafer W to and from the substrate storage, and can smoothly transfer the polishing member PP to and from the polishing member storage.

The inspection main body 10 includes a moving device 41 that is capable of moving the first stage (substrate support unit 40) and the second stage (polishing-member support unit 50) in a horizontal direction. The moving device 41 arranges the second stage in a direction perpendicular to the polishing member storage (polishing member storage container 70) with the transfer device 60 as a base point, when the polishing member PP is loaded onto or unloaded from the second stage. The transfer device 60 rotates the transfer arm 64 by 90° with the polishing member PP being held by the transfer arm 64 to transfer the polishing member PP between second stage and the polishing member storage. Thus, the inspection device 1 can transfer the polishing member PP between the polishing member storage and the second stage with high speed and accuracy.

The transfer arm 64 that has transferred the polishing member PP immediately above the second stage (polishing-member support unit 50), the second stage, or both move in a vertical direction to reduce a gap between the polishing member PP and the second stage so that the polishing member PP is passed from the transfer arm 64 to the second stage. Thus, the inspection device 1 can precisely place the polishing member PP onto the second stage. Moreover, it is not necessary to provide support pins for receiving a polishing member PP or the like to the second stage, and therefore a configuration is simplified and the cost can be reduced.

The inspection device further includes a position adjustment device 80 that adjusts a horizontal position of the polishing member PP. The position adjustment device is disposed between the transfer device 60 and the polishing member storage (polishing member storage container 70). By using the position adjustment device 80, the inspection device 1 can accurately place the polishing member PP on the second stage (polishing-member support unit 50) or into the polishing member storage container 70.

When the transfer arm 64 transfers the polishing member PP that has been used to the polishing member storage (polishing member storage container 70), the transfer device 60 places the polishing member PP on the position adjustment device 80, and rotates a position of the polishing member PP in a longitudinal direction by 90°. When the transfer arm 64 transfers the replacing polishing member PP from the polishing member storage, the transfer device 60 places the polishing member PP on the position adjustment device 80, rotates a position of the polishing member PP in the longitudinal direction by 90°, and adjusts the position of the polishing member PP in a horizontal direction. Thus, in the case where the polishing member PP is returned back to the polishing member storage container 70, the inspection device 1 can perform the adjustment within a short period. In the case where the polishing member PP is transferred onto the second stage (polishing-member support unit 50), the horizontal position of the polishing member PP can be sufficiently adjusted to increase the accuracy of the positioning.

The position adjustment device 80 includes a turning mechanism 81 that turns the polishing member PP by a set angle, and a clamp mechanism 86 that clamps the polishing member PP in a horizontal direction. Thus, the inspection device 1 can appropriately adjust the horizontal position of the polishing member PP.

The turning mechanism 81 includes a table 82 on which the polishing member PP is placed, and a turning drive 83 that turns the table 82. The clamp mechanism 86 includes slider moving portions 87 disposed on both sides of the table 82, respectively. The slider moving portions 87 disposed on both sides respectively include sliders 89 movable in a direction approaching each other and in a direction moving away from each other. The slider moving portions 87 clamp the polishing member PP placed on the table 82 with the sliders 89 so that a horizontal position of the polishing member PP is adjusted. Thus, the inspection device 1 can precisely adjust the horizontal position of the polishing member PP.

A loader 20 according to a second embodiment of the present disclosure includes a substrate storage (FOUP 29) that stores one or more substrates (wafers W) to be in contact with one or more contact probes 33, a polishing member storage (polishing member storage container 70) that stores one or more polishing members PP capable of polishing the one or more contact probes 33, and a transfer device 60 including a transfer arm 64 that transfers a substrate between a first stage (substrate support unit 40) and the substrate storage, and transfers a polishing member PP between a second stage (polishing-member support unit 50) and the polishing member storage. The first stage (substrate support unit 40) supports the substrate. The second stage (polishing-member support unit 50) is disposed in a vicinity of the first stage and supports the polishing member PP. The transfer arm 64 includes a first holder 67 capable of holding the substrate, and a second holder 68 capable of holding the polishing member PP at a different position from the first holder 67.

A transfer method according to a third embodiment of the present disclosure is a transfer method performed in an inspection device that includes a first stage (substrate support unit 40) that supports a substrate (wafer W) to be in contact with one or more contact probes 33, a second stage (polishing-member support unit 50) that is disposed in a vicinity of the first stage, and supports a polishing member PP capable of polishing the one or more contact probes 33, a substrate storage (FOUP 29) that stores substrates including the substrate, a polishing member storage (polishing member storage container 70) that stores one or more polishing members PP including the polishing member PP, and a transfer device 60 including a transfer arm 64 that transfers the substrate between the first stage and the substrate storage, and transfers the polishing member PP between the second stage and the polishing member storage. The transfer method includes a) holding the substrate with a first holder 67 of the transfer arm 64 to transfer the substrate, and b) holding the polishing member with a second holder 68 of the transfer arm 64 to transfer the polishing member PP, where the second holder 68 is disposed in a position different from the first holder 67. A workload of a user can be reduced, and work efficiency can be increased also in the second and third embodiments.

The inspection device 1, the loader 20, and the transfer method according to the embodiment disclosed above are merely explanatory and are not restrictive. Various modifications and improvements can be made in the embodiments without departing from the scope and spirit of the appended claims. The features described in the above embodiments can have another configuration or may be combined together as long as such configuration or combination will not cause contradiction.

What is claimed is:

1. An inspection device comprising:
a first stage that supports a substrate to be in contact with contact one or more probes;
a second stage that is disposed in a vicinity of the first stage, and supports a polishing member capable of polishing the one or more contact probes;
a substrate storage that stores one or more substrates including the substrate;
a polishing member storage that stores one or more polishing members including the polishing member; and
a transfer device including a transfer arm that transfers the substrate between the first stage and the substrate storage, and transfers the polishing member between the second stage and the polishing member storage,
wherein the transfer arm includes a first holder capable of holding the substrate, and a second holder capable of holding the polishing member at a different position from the first holder.

2. The inspection device according to claim 1,
wherein the transfer arm includes an end effector that is in a shape of a plate, and
the end effector includes
one or more suction ports arranged on an upper surface of the end effector, the one or more suction ports constituting one of the first holder or the second holder, and
one or more suction pads arranged on a lower surface of the end effector, the one or more suction pads constituting the other one of the first holder or the second holder.

3. The inspection device according to claim 2,
wherein the end effector includes an ejection mechanism that applies suction pressure to the polishing member via the one or more suction pads constituting the second holder to hold the polishing member.

4. The inspection device according to claim 2,
wherein each of the one or more suction pads includes a pad main body to be in contact with the polishing member, the pad main body having a tapered shape, and
the end effector includes a suction channel inside the end effector, the suction channel communicating with an inside of the pad main body and being capable of applying suction pressure to the pad main body.

5. The inspection device according to claim 2,
wherein the end effector includes a base plate portion, and a pair of fork plate portions projected from the base plate portion, and
the suction pads are provided to each of the base plate portions and the pair of fork plate portions.

6. The inspection device according to claim 1,
wherein the inspection device includes
an inspection main body including the first stage and the second stage, and
a loader disposed in a vicinity of the inspection main body, and
the loader includes the substrate storage, the transfer device, and the polishing member storage disposed in an order mentioned in a direction parallel to the inspection main body in a plan view.

7. The inspection device according to claim 6,
wherein the transfer device includes
a lifting drive that lifts and lowers the transfer arm in a vertical direction,
a rotation drive that rotates the transfer arm about a vertical axis, and
a reciprocation drive that linearly moves the transfer arm to reciprocate.

8. The inspection device according to claim 7,
wherein, when the substrate storage stores a plurality of substrates, the substrate storage stores the plurality of substrates in the vertical direction,
when the polishing member storage stores a plurality of polishing members, the polishing member storage stores the plurality of polishing members in the vertical direction,
the transfer device adjusts a height of the transfer arm with lifting and lowering of the lifting drive, adjusts a reciprocation direction of the transfer arm with rotation of the rotation drive, and allows the transfer arm to access the plurality of substrates in the substrate storage or the plurality of polishing members in the polishing member storage with a reciprocating movement of the reciprocation drive.

9. The inspection device according to claim 6,
wherein the inspection main body includes a moving device that is capable of moving the first stage and the second stage in a horizontal direction,
the moving device arranges the second stage in a direction perpendicular to the polishing member storage with the transfer device as a base point, when the polishing member is loaded onto or unloaded from the second stage, and
the transfer device rotates the transfer arm by 90° with the polishing member being held by the transfer arm to transfer the polishing member between the second stage and the polishing member storage.

10. The inspection device according to claim 9,
wherein the transfer arm that has transferred the polishing member immediately above the second stage, the second stage, or both the transfer arm and the second stage move in a vertical direction to reduce a gap between the polishing member and the second stage so that the polishing member is passed from the transfer arm to the second stage.

11. The inspection device according to claim 1, further comprising:
a position adjustment device that adjusts a horizontal position of the polishing member, the position adjustment device being disposed between the transfer device and the polishing member storage.

12. The transfer device according to claim 11,
wherein, when the transfer arm transfers the polishing member that has been used to the polishing member storage, the transfer device places the polishing member on the position adjustment device, and rotates a position of the polishing member in a longitudinal direction by 90°, and
when the transfer arm transfers the polishing member used for replacement from the polishing member storage, the transfer device places the polishing member on the position adjustment device, rotates a position of the polishing member in the longitudinal direction by 90°, and adjusts the position of the polishing member in a horizontal direction.

13. The inspection device according to claim 11,
wherein the position adjustment device includes
a turning mechanism that turns the polishing member by a set angle, and
a clamp mechanism that clamps the polishing member in a horizontal direction.

14. The inspection device according to claim 13,
wherein the turning mechanism includes a table on which the polishing member is placed, and a turning drive that turns the table,
the clamp mechanism includes slider moving portions disposed on both sides of the table, respectively, and
the slider moving portions disposed on both sides respectively include sliders movable in a direction approaching each other and in a direction moving away from each other, and the slider moving portions clamp the polishing member placed on the table with the sliders so that a horizontal position of the polishing member is adjusted.

15. A loader comprising:
a substrate storage that one or more stores substrates to be in contact with one or more contact probes;
a polishing member storage that stores one or more polishing members capable of polishing the one or more contact probes; and
a transfer device including a transfer arm that transfers a substrate between a first stage and the substrate storage, and transfers a polishing member between a second stage and the polishing member storage, the first stage supporting the substrate, and the second stage being disposed in a vicinity of the first stage and supporting the polishing member,
wherein the transfer arm includes a first holder capable of holding the substrate, and a second holder capable of holding the polishing member at a different position from the first holder.

16. A transfer method comprising:
by an inspection device including
a first stage that supports a substrate to be in contact with one or more contact probes,
a second stage that is disposed in a vicinity of the first stage, and supports a polishing member capable of polishing the one or more contact probes,
a substrate storage that stores one or more substrates including the substrate,
a polishing member storage that stores one or more polishing members including the polishing member, and
a transfer device having a transfer arm that transfers the substrate between the first stage and the substrate storage, and transfers the polishing member between the second stage and the polishing member storage,
a) holding the substrate with a first holder of the transfer arm to transfer the substrate; and
b) holding the polishing member with a second holder of the transfer arm to transfer the polishing member, the second holder being disposed in a position different from the first holder.
